(19) United States
(12) Patent Application Publication
(10) Pub. No.: US 2025/0351506 A1
(43) Pub. Date: Nov. 13, 2025

(54) Device-Level Interconnects for Stacked Transistor Structures and Methods of Fabrication Thereof

(71) Applicant: Taiwan Semiconductor Manufacturing Company, Ltd., Hsin-Chu (TW)

(72) Inventors: Wei-Yip Loh, Hsinchu City (TW); Liang-Yueh Ou Yang, New Taipei City (TW); Hung-Yi Huang, Hsinchu City (TW); Harry Chien, Chandler, AZ (US); Chun-Chieh Lin, Taichung City (TW)

(21) Appl. No.: 19/280,561

(22) Filed: Jul. 25, 2025

Related U.S. Application Data
(63) Continuation of application No. 18/520,853, filed on Nov. 28, 2023.
(60) Provisional application No. 63/506,892, filed on Jun. 8, 2023.

(51) Int. Cl. H10D 64/01; H10D 30/43; H10D 30/67; H10D 62/10; H10D 84/01; H10D 84/03; H10D 84/85

(52) U.S. Cl. CPC H10D 64/01; H10D 30/43; H10D 30/6735; H10D 30/6757; H10D 62/121; H10D 84/0186; H10D 84/038; H10D 84/85

(57) ABSTRACT

Device-level interconnects having high thermal stability for stacked device structures are disclosed herein. An exemplary stacked semiconductor structure includes an upper source/drain contact disposed on an upper epitaxial source/drain, a lower source/drain contact disposed on a lower epitaxial source/drain, and a source/drain via connected to the upper source/drain contact and the lower source/drain contact. The source/drain via is disposed on the upper source/drain contact, the source/drain via extends below the upper source/drain contact, and the source/drain via includes ruthenium and aluminum. In some embodiments, the source/drain via includes a ruthenium plug wrapped by an aluminum liner. In some embodiments, the source/drain via includes a ruthenium aluminide plug. In some embodiments, the source/drain via includes a ruthenium plug wrapped by a ruthenium aluminide liner. In some embodiments, the source/drain via extends below a top of the lower epitaxial source/drain.

This is a divisional application of U.S. Provisional patent application Ser. No. 18/520,853, filed Nov. 28, 2023, which is a non-provisional application of and claims benefit of U.S. Provisional Patent Application Ser. No. 63/506,892, filed Jun. 8, 2023, the entire disclosures of which are incorporated herein by reference.

### BACKGROUND

The integrated circuit (IC) industry has experienced exponential growth. Technological advances in IC materials and design have produced generations of ICs, where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, as stacked device structures are introduced to enable further density reduction for advanced IC technology nodes, frontside interconnect structures and backside interconnect structures may be needed to facilitate electrical connection to and/or operation of devices of the stacked device structures, such as an upper transistor and a lower transistor thereof. Although existing interconnect structures have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A and FIG. 1B are cross-sectional views of a stacked device structure, in portion or entirety, according to various aspects of the present disclosure.

FIG. 2 is a flow chart of a method, in portion or entirety, for fabricating a device-level interconnect structure for a stacked device structure, such as the stacked device structure of FIG. 1A and FIG. 1B, according to various aspects of the present disclosure.

FIGS. 3A-13A and FIGS. 3B-13B are cross-sectional views of a stacked device structure, in portion or entirety, at various fabrication stages associated with the method of FIG. 2 according to various aspects of the present disclosure.

FIG. 14 is a perspective view of the stacked device structure, in portion or entirety, of FIG. 13A and FIG. 13B according to various aspects of the present disclosure.

FIG. 15 is a cross-sectional view of another stacked device structure, in portion or entirety, that includes a device-level interconnect that may be fabricated according to the method of FIG. 2 according to various aspects of the present disclosure.

FIG. 16A is a perspective view of yet another stacked device structure, in portion or entirety, that includes a device-level interconnect that may be fabricated according to the method of FIG. 2 according to various aspects of the present disclosure.

FIGS. 16B-16D are cross-sectional views of the stacked device structure, in portion or entirety, of FIG. 16A according to various aspects of the present disclosure.

FIGS. 17A-20A and FIGS. 17B-20B are cross-sectional views of the stacked device structure, in portion or entirety, of FIGS. 16A-16D at various fabrication stages according to various aspects of the present disclosure.

FIG. 21 is a flow chart of a method, in portion or entirety, for fabricating a device-level interconnect structure for a stacked device structure, such as those described herein, according to various aspects of the present disclosure.

### DETAILED DESCRIPTION

The present disclosure relates generally to device-level interconnects for stacked device structures, such as a transistor stack having an n-type field effect transistor (NFET) and a p-type field effect transistor (PFET) (i.e., a complementary field effect transistor (CFET)).

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features—but not mathematically or perfectly vertical and horizontal.

Stacked transistor structures can provide further density reduction for advanced integrated circuit (IC) technology nodes (particularly as they advance to 3 nm (N3) and below), especially when the stacked transistor structures include multigate devices, such as fin-like field effect transistors (FinFETs), gate-all-around (GAA) transistors including nanowires and/or nanosheets, other types of multigate devices, etc. Stacked transistor structures vertically stack transistors. For example, a stacked transistor structure can include a first transistor (i.e., an upper/top transistor) disposed over a second transistor (i.e., a lower/bottom transistor). The transistor stack can provide a CFET when the first transistor and the second transistor are of opposite conductivity type (i.e., an n-type transistor and a p-type transistor).

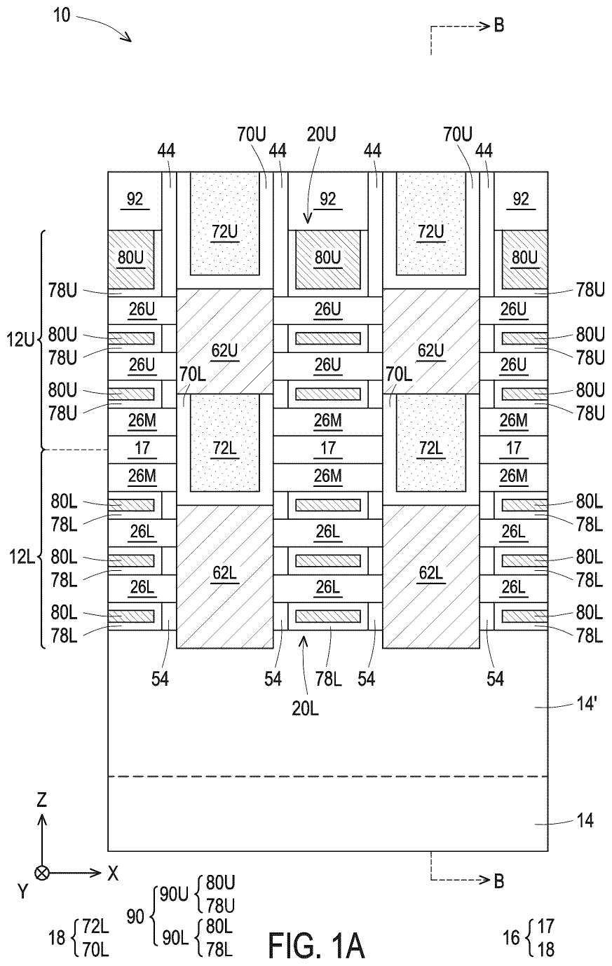

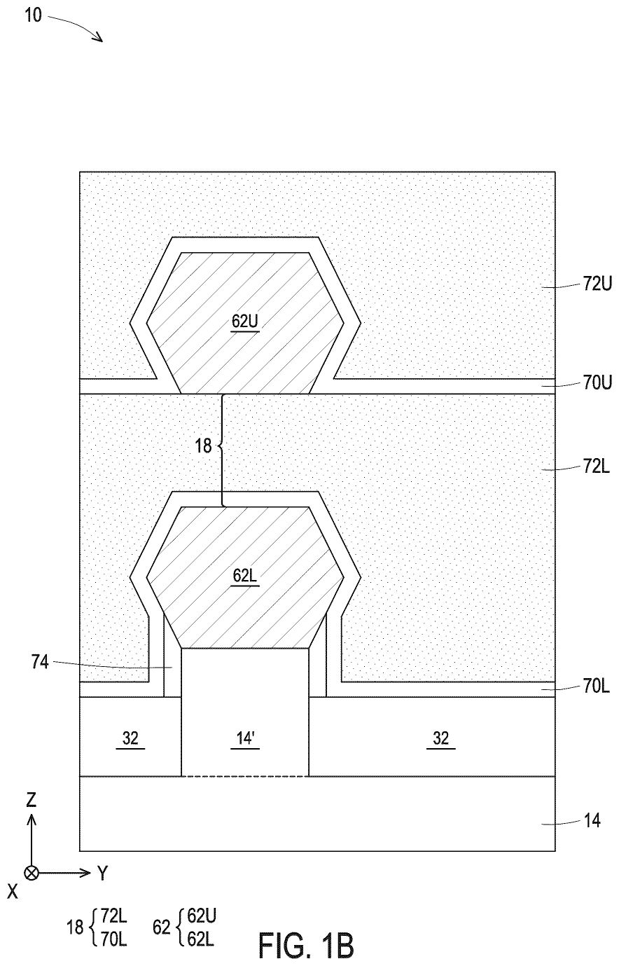

FIG. 1A is a fragmentary cross-sectional view of a stacked device structure 10, in portion or entirety, according to various aspects of the present disclosure. FIG. 1B is a fragmentary cross-sectional view of stacked device structure 10, in portion or entirety, along line B-B of FIG. 1A according to various aspects of the present disclosure. Stacked device structure 10 includes a device stack, such as an upper device 12U vertically stacked over a lower device 12L, disposed over a substrate 14. In the depicted embodiment, device 12U and device 12L are stacked back-to-front. For example, a backside of device 12U is attached and/or bonded to a frontside of device 12L. An insulation structure 16 is disposed between and separates device 12U and device 12L. Insulation structure 16 may be a single layer/feature or a multilayer/feature structure, and in the depicted embodiment, includes an insulation structure 17 and an insulation structure 18. In the depicted embodiment, stacked device structure 10 is fabricated monolithically, and thus can be referred to as a monolithic stacked device structure 10. In some embodiments, stacked device structure 10 is fabricated sequentially, and thus can be referred to as a sequential stacked device structure 10. FIG. 1A and FIG. 1B have been simplified for the sake of clarity to better understand the inventive concepts of the present disclosure. Additional features can be added in stacked device structure 10, and some of the features described below can be replaced, modified, or eliminated in other embodiments of stacked device structure 10.

In FIG. 1A and FIG. 1B, device 12U and device 12L each include at least one electrically functional device, such as an upper transistor 20U and a lower transistor 20L, respectively. Stacked device structure 10 thus includes a transistor stack having a top transistor (e.g., transistor 20U) and a bottom transistor (e.g., transistor 20L) separated and/or electrically isolated from one another by isolation structure 16. In some embodiments, transistor 20L and transistor 20U are transistors of an opposite conductivity type. For example, transistor 20L is a p-type transistor, and transistor 20U is an n-type transistor, or vice versa. In such embodiments, transistor 20L and transistor 20U form a CFET. In some embodiments, transistor 20L and transistor 20U are transistors of a same conductivity type. For example, transistor 20L and transistor 20U are both n-type transistors or both p-type transistors.

Device 12U includes various features and/or components, such as semiconductor layers 26U, semiconductor layers 26M, gate spacers 44, inner spacers 54, epitaxial source/drains 62U, a contact etch stop layer (CESL) 70U, an interlayer dielectric (ILD) layer 72U, a gate dielectric 78U and a gate electrode 80U (collectively referred to as a gate stack 90U), and hard masks 92. Device 12L also includes various features and/or components, such as mesas 14′ (e.g., extensions of substrate 14), semiconductor layers 26L, semiconductor layers 26M, isolation features 32, inner spacers 54, epitaxial source/drains 62L, a CESL 70L, an ILD layer 72L, and a gate dielectric 78L and a gate electrode 80L (collectively referred to as a gate stack 90L). In the depicted embodiment, gate stack 90U is separated and/or electrically isolated from gate stack 90L by insulation structure 17, and gate stack 90U and gate stack 90L are collectively referred to as a gate 90 of stacked device structure 10, such as a metal gate or a high-k/metal gate of a CFET. In some embodiments, insulation structure 17 includes a dielectric material, which may include silicon, oxygen, carbon, nitrogen, other suitable dielectric constituent, or a combination thereof (e.g., silicon oxide, silicon nitride, silicon oxynitride, silicon carbide, silicon carbonitride, silicon oxycarbide, silicon oxycarbonitride, or a combination thereof). In furtherance of the depicted embodiment, epitaxial source/drains 62U are separated and/or electrically isolated from epitaxial source/drains 62L by insulation structure 18. In some embodiments, insulation structure 18 may be formed by a portion of CESL 70L and ILD layer 72L.

In the depicted embodiment, transistor 20L is a GAA transistor. For example, transistor 20L has two channels provided by semiconductor layers 26L (also referred to as channel layers), which are suspended over substrate 14 and extend between respective source/drains (e.g., epitaxial source/drains 62L). In some embodiments, transistor 20L includes more or less channels (and thus more or less semiconductor layers 26L). Transistor 20L further has gate stack 90L disposed over its semiconductor layers 26L and between its epitaxial source/drains 62L, and inner spacers 54 are disposed between its gate stack 90L and its epitaxial source/drains 62L. Along a gate widthwise direction (e.g., in an X-Z plane), gate stack 90L is over top semiconductor layer 26L, between semiconductor layers 26L, and between bottom semiconductor layer 26L and substrate 14. Along a gate lengthwise direction (e.g., in a Y-Z plane), gate stack 90L wraps around semiconductor layers 26L. During operation of the GAA transistor, current can flow through semiconductor layers 26L and between epitaxial source/drains 62L. Semiconductor layers 26M are suspended over substrate 14 and extend between respective insulation structures 18, and insulation structures 17 are disposed between semiconductor layers 26M of device 12L and semiconductor layers 26M of device 12U.

In the depicted embodiment, transistor 20U is also a GAA transistor. For example, transistor 20U has two channels provided by semiconductor layers 26U (also referred to as channel layers), which are suspended over substrate 14 and extend between respective source/drains (e.g., epitaxial source/drains 62U). In some embodiments, transistor 20U includes more or less channels (and thus more or less semiconductor layers 26U). Transistor 20U further has gate stack 90U disposed over its semiconductor layers 26U and between its epitaxial source/drains 62U, gate stack 90U disposed between respective gate spacers 44, inner spacers 54 disposed between its gate stack 90U and its epitaxial source/drains 62U, and hard mask 92 disposed over gate stack 90U. Along a gate widthwise direction, gate stack 90U is over top semiconductor layer 26U, between semiconductor layers 26U, and between bottom semiconductor layer 26U and semiconductor layer 26M. Along a gate lengthwise direction, gate stack 90U wraps around semiconductor layers 26U. During operation of the GAA transistor, current can flow through semiconductor layers 26U and between epitaxial source/drains 62U.

Substrate 14, semiconductor layers 26U, semiconductor layers 26M, and semiconductor layers 26L include an elementary semiconductor, such as silicon and/or germanium; a compound semiconductor, such as silicon carbide, gallium arsenide, gallium phosphide, indium phosphide, indium arsenide, indium antimonide, or a combination thereof; an alloy semiconductor, such as SiGe, GaAsP, AlInAs, AlGaAs, GaInAs, GaInP, GaInAsP, or a combination thereof; or a combination thereof. In the depicted embodiment, substrate 14, semiconductor layers 26U, semiconductor layers 26M, and semiconductor layers 26L include silicon. In some embodiments, semiconductor layers 26U and semiconductor layers 26L include different semiconductor materials, such as silicon and silicon germanium, respectively, or vice versa. In some embodiments, substrate 14 is a semiconductor-on-insulator substrate, such as a silicon-on-insulator substrate, a silicon germanium-on-insulator substrate, or a germanium-on-insulator substrate. Substrate 14 (including mesas 14′ extending therefrom) may include various doped regions, such as p-wells and n-wells. The n-wells are doped with n-type dopants, such as phosphorus, arsenic, other n-type dopant, or a combination thereof. The p-wells are doped with p-type dopants, such as boron, indium, other p-type dopant, or a combination thereof.

Isolation features 32 electrically isolate active device regions and/or passive device regions. For example, isolation features 32 separate and electrically isolate mesas 14′ from each other and/or other device regions/features. Isolation features 32 include silicon oxide, silicon nitride, silicon oxynitride, other suitable isolation material (for example, including silicon, oxygen, nitrogen, carbon, etc.), or a combination thereof. Isolation features 32 may have a multilayer structure. For example, isolation features 32 include a bulk dielectric (e.g., an oxide layer) over a dielectric liner (for example, silicon nitride, silicon oxide, silicon oxynitride, silicon oxycarbonitride, or a combination thereof). In another example, isolation features 32 include a bulk dielectric over a doped liner, such as a boron silicate glass (BSG) liner and/or a phosphosilicate glass (PSG) liner. Dimensions and/or characteristics of isolation features 32 are configured to provide shallow trench isolation (STI) structures, deep trench isolation (DTI) structures, local oxidation of silicon (LOCOS) structures, other suitable isolation structures, or a combination thereof. In the depicted embodiment, isolation features 32 may be STIs.

Gate spacers 44 are disposed along sidewalls of upper portions of gate stack 90U, inner spacers 54 are disposed under gate spacers 44 along sidewalls of gate stack 90U and/or gate stack 90L, and fin spacers 74 are disposed along sidewalls of mesas 14′. Inner spacers 54 are between semiconductor layers 26 and between bottom semiconductor layers 26 and mesas 14′. Gate spacers 44, inner spacers 54, and fin spacers 74 include a dielectric material, which may include silicon, oxygen, carbon, nitrogen, other suitable dielectric constituent, or a combination thereof (e.g., silicon oxide, silicon nitride, silicon oxynitride, silicon carbide, silicon carbonitride, silicon oxycarbide, silicon oxycarbonitride, or a combination thereof). Gate spacers 44, inner spacers 54, and fin spacers 74 may include different materials and/or different configurations (e.g., different numbers of layers). In some embodiments, gate spacers 44, inner spacers 54, fin spacers 74, or a combination thereof have a multilayer structure. In some embodiments, gate spacers 44 and/or fin spacers 74 include more than one set of spacers, such as seal spacers, offset spacers, sacrificial spacers, dummy spacers, main spacers, or a combination thereof. The various sets of spacers may have different compositions.

Gate 90 is disposed between epitaxial source/drain stacks 62, and each epitaxial source/drain stack 62 includes a respective epitaxial source/drain 62U, a respective epitaxial source/drain 62L, and a respective insulation structure disposed therebetween. Epitaxial source/drains 62L and epitaxial source/drains 62U have the same or different compositions and/or materials depending on configurations of their respective transistors. Epitaxial source/drains 62L and epitaxial source/drains 62U may be doped with n-type dopants and/or p-type dopants. In some embodiments, epitaxial source/drains 62L and/or epitaxial source/drains 62U include silicon that may be doped with carbon, phosphorous, arsenic, other n-type dopant, or a combination thereof (e.g., Si:C epitaxial source/drains, Si:P epitaxial source/drains, or Si:C:P epitaxial source/drains). In some embodiments, epitaxial source/drains 62L and/or epitaxial source/drains 62U include silicon germanium or germanium, which may be doped with boron, other p-type dopant, or a combination thereof (e.g., Si:Ge:B epitaxial source/drains). In the depicted embodiment, epitaxial source/drains 62L include silicon germanium doped with boron, and epitaxial source/drains 62U include silicon doped with phosphorous. In some embodiments, epitaxial source/drains 62L and/or epitaxial source/drains 62U include more than one epitaxial semiconductor layer, where the epitaxial semiconductor layers may include the same or different materials and/or the same or different dopant concentrations. In some embodiments, epitaxial source/drains 62L and/or epitaxial source/drains 62U include materials and/or dopants that achieve desired tensile stress and/or compressive stress in adjacent channel regions (e.g., formed by semiconductor layers 26U and semiconductor layers 26L). As used herein, source/drain region, epitaxial source/drain, epitaxial source/drain feature, etc. may refer to a source of a device (e.g., transistor 20U and/or transistor 20L), a drain of a device (e.g., transistor 20U and/or transistor 20L), or a source and/or a drain of multiple devices.

ILD layer 72U and ILD layer 72L includes a dielectric material including, for example, silicon oxide, carbon doped silicon oxide, silicon nitride, silicon oxynitride, tetraethyl orthosilicate (TEOS)-formed oxide, BSG, PSG, borophosphosilicate glass (BPSG), fluorosilicate glass (FSG), Black Diamond® (Applied Materials of Santa Clara, California), xerogel, aerogel, amorphous fluorinated carbon, parylene, benzocyclobutene-based (BCB) dielectric material, SiLK (Dow Chemical, Midland, Michigan), polyimide, other suitable dielectric material, or a combination thereof. In some embodiments, ILD layer 72U and/or ILD layer 72L includes a dielectric material having a dielectric constant that is less than a dielectric constant of silicon dioxide. CESL 70L and CESL 70U include a material different than a material of ILD layer 72U and ILD layer 72L, respectively. For example, where ILD layer 72U and ILD layer 72L include a low-k dielectric material that includes silicon and oxygen, CESL 70L and CESL 70U may include silicon and nitrogen and/or carbon. ILD layer 72U, ILD layer 72L CESL 70L, CESL 70U, or a combination thereof may include a multilayer structure.

Gate dielectrics 78 includes at least one dielectric gate layer. In some embodiments, gate dielectrics 78 include an interfacial layer that includes a dielectric material, such as SiO₂, SiGeOₓ, HfSiO, SiON, other dielectric material, or a combination thereof. In some embodiments, gate dielectrics 78 include a high-k dielectric layer. The high-k dielectric layer includes a high-k dielectric material, which generally refers to dielectric materials having a dielectric constant that is greater than a dielectric constant of silicon dioxide (k≈3.9), such as HfO₂, HfSiO, HfSiO₄, HfSiON, HfLaO, HfTaO, HfTiO, HfZrO, HfAlOx, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr)TiO₃ (BST), Si₃N₄, HfO₂—Al₂O₃, other high-k dielectric material, or a combination thereof. For example, gate dielectrics 78 include a hafnium-based oxide (e.g., HfO₂) layer and/or a zirconium-based oxide (e.g., ZrO₂) layer. In some embodiments, the interfacial layer and/or the high-k dielectric layer has a multilayer structure.

Gate electrode 80U and gate electrode 80L are disposed over respective gate dielectrics 78. Gate electrode 80U and gate electrode 80L each include at least one electrically conductive gate layer. The electrically conductive gate layer includes an electrically conductive material, such as Al, Cu, Ti, Ta, W, Mo, Co, TaN, NiSi, CoSi, TiN, WN, TiAl, TiAlN, TaCN, TaC, TaSiN, other electrically conductive material, or a combination thereof. In some embodiments, gate electrode 80U and/or gate electrode 80L include a work function layer. The work function layer is a conductive layer tuned to have a desired work function, such as an n-type work function or a p-type work function. The work function layer includes work function metal(s) and/or alloys thereof, such as Ti, Ta, Al, Ag, Mn, Zr, W, Ru, Mo, TiC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAlN, or a combination thereof. In some embodiments, gate electrode 80U and/or gate electrode 80L include a bulk layer over gate dielectric 78 and/or the work function layer. The bulk layer includes a suitable conductive material, such as Al, W, Cu, Ti, Ta, TiN, TaN, polysilicon, other suitable metal(s) and/or alloys thereof, or a combination thereof. In some embodiments, gate electrode 80U and/or gate electrode 80L include a barrier (blocking) layer over the work function layer and/or gate dielectric 78. The barrier layer includes a material that prevents or eliminates diffusion and/or reaction of constituents between adjacent layers and/or promotes adhesion between adjacent layers, such as between the work function layer and the bulk layer. In some embodiments, the barrier layer includes metal and nitrogen, such as titanium nitride, tantalum nitride, tungsten nitride (e.g., W₂N), titanium silicon nitride (TiSiN), tantalum silicon nitride (TaSiN), other suitable metal nitride, or a combination thereof.

Hard masks 92 include a material that is different than ILD layer 72U and/or subsequently formed ILD layers to achieve etch selectivity during subsequent etching processes. In some embodiments, hard masks 92 include silicon and nitrogen and/or carbon, such as silicon nitride, silicon oxynitride, silicon carbide, silicon oxycarbide, silicon carbonitride, silicon oxycarbonitride, other silicon nitride, other silicon carbide, or a combination thereof. In some embodiments, hard masks 92 include metal and oxygen and/or nitrogen, such as aluminum oxide (e.g., AlO or Al₂O₃), aluminum nitride (e.g., AlN), aluminum oxynitride (e.g., AlON), zirconium oxide, zirconium nitride, hafnium oxide (e.g., HfO or HFO₂), zirconium aluminum oxide (e.g., ZrAlO), other metal oxide, other metal nitride, or a combination thereof.

Stacked device structure 10 may undergo middle-end-of-line (MOL or MEOL) processing and back-end-of-line (BEOL) processing. BEOL generally encompasses processes related to fabricating metallization layers that electrically connect IC devices (e.g., transistors) and/or components of the IC devices (e.g., gates and/or source/drains) fabricated during front-end-of-line (FEOL) processing to one another and/or external devices, thereby enabling operation of the IC devices. The metallization layers can route signals between the IC devices and/or the components of the IC devices and/or distribute signals (e.g., clock signals, voltage signals, ground signals, other signals, or a combination thereof) to the IC devices and/or the components of the IC devices. Often, each metallization layer (also referred to as a metallization level) includes at least one interconnect structure disposed in an insulator layer, such as a metal line and a via disposed in a dielectric layer, where the via connects the metal line to a metal line of an interconnect structure in a different metallization layer. Metal lines and vias of the metallization layers can be referred to as BEOL features or global interconnects.

MOL generally encompasses processes related to fabricating interconnect structures that physically and/or electrically connect FEOL features (e.g., electrically active features of the IC devices) to a first metallization layer (level) formed during BEOL, such as contacts that connect a gate and/or a source/drain of a transistor to the first metallization layer. An MOL interconnect structure (also referred to as a device-level interconnect) may include a device-level contact (e.g., a source/drain contact) and a local contact (e.g., a source/drain via) disposed in an insulator layer. The device-level contact may connect an electrically active feature (e.g., source/drain) of an IC device (e.g., transistor) to the source/drain via, and the source/drain via may connect the source/drain contact to the first metallization layer.

To facilitate electrical connection to transistor 20U and transistor 20L, stacked device structure 10 may undergo frontside MOL processing (e.g., to form frontside source/drain contacts and source/drain vias thereto), backside MOL processing (e.g., to form backside source/drain contacts and source/drain vias thereto), frontside BEOL processing (e.g., to form frontside routing layers), backside BEOL processing (e.g., to form backside routing layers), or a combination thereof. The additional processing associated with providing stacked device structure 10 with frontside electrical connection and backside electrical connection subjects MOL interconnect structures to high thermal stress that can degrade their reliability and correspondingly degrade performance of stacked device structure 10. MOL interconnect structures are thus needed that can withstand high temperature MOL processing and/or BEOL processing while exhibiting low resistance and/or low capacitance attributes. The present disclosure provides thermally stable device-level interconnects for stacked transistor structures, such as stacked transistor structure 10, for high temperature processing, along with methods of fabrication thereof, as described herein in the following pages and/or drawings.

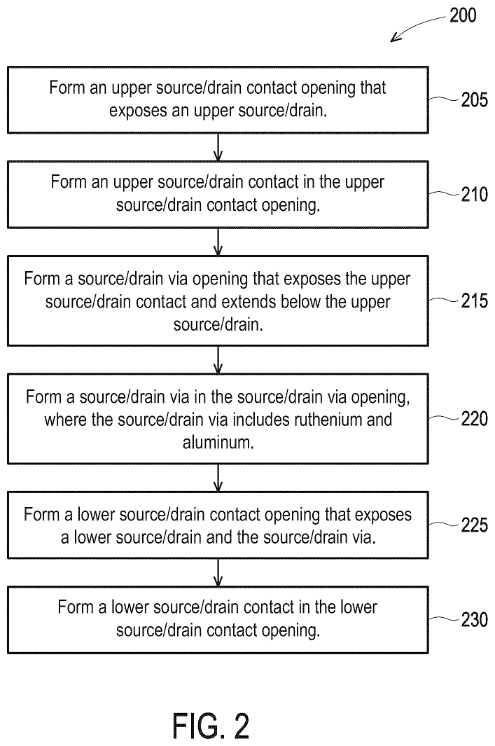

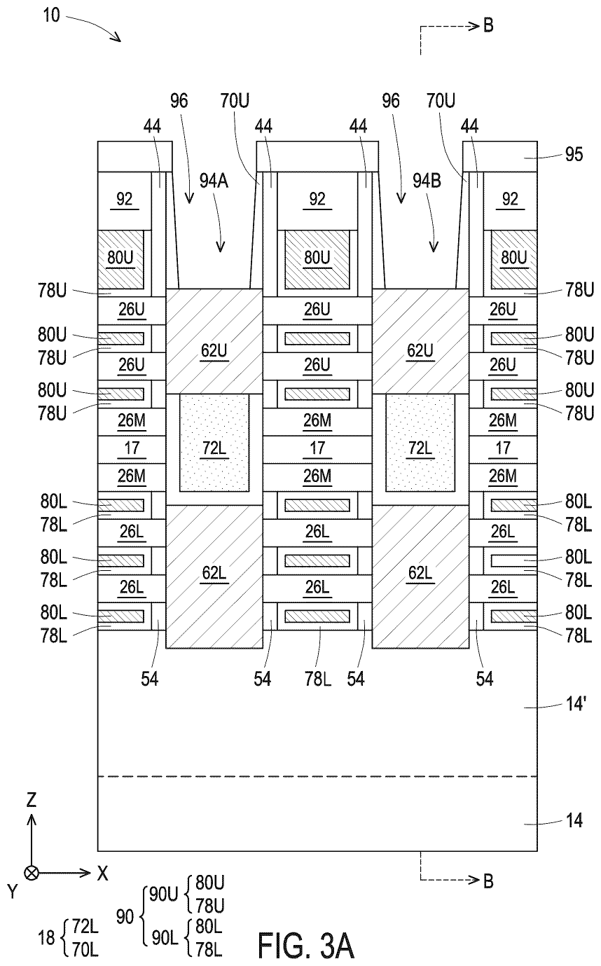

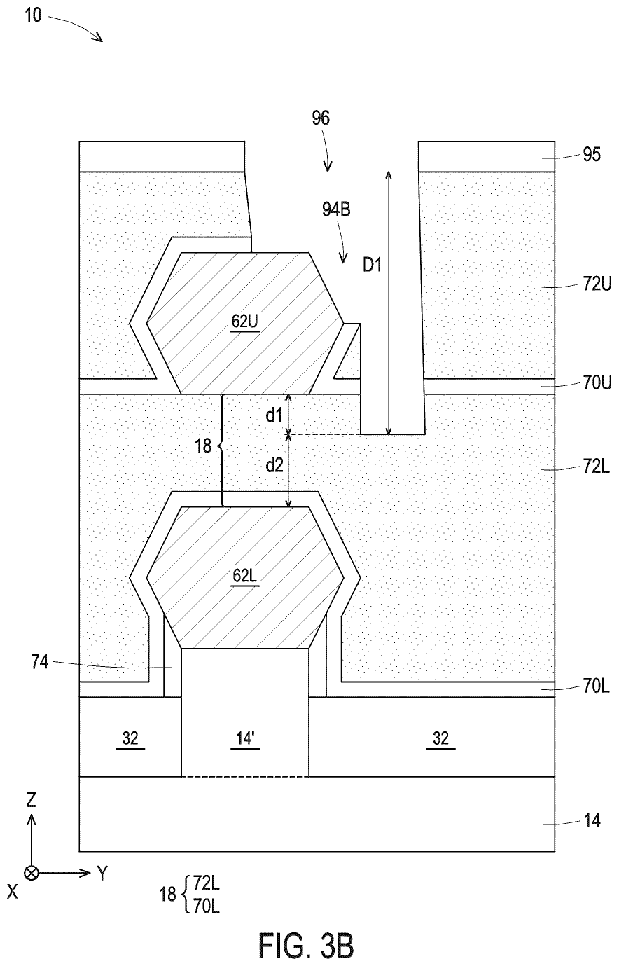

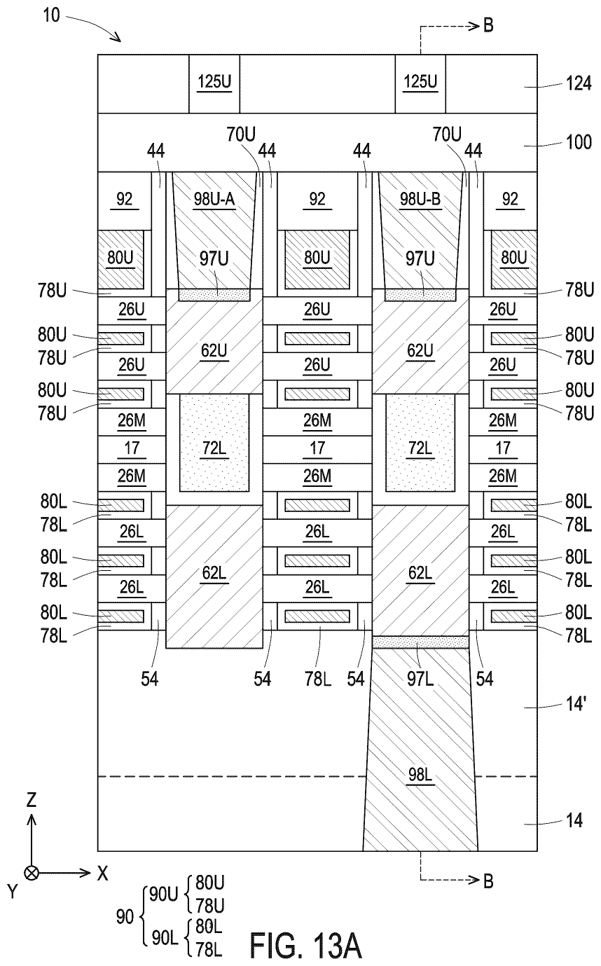

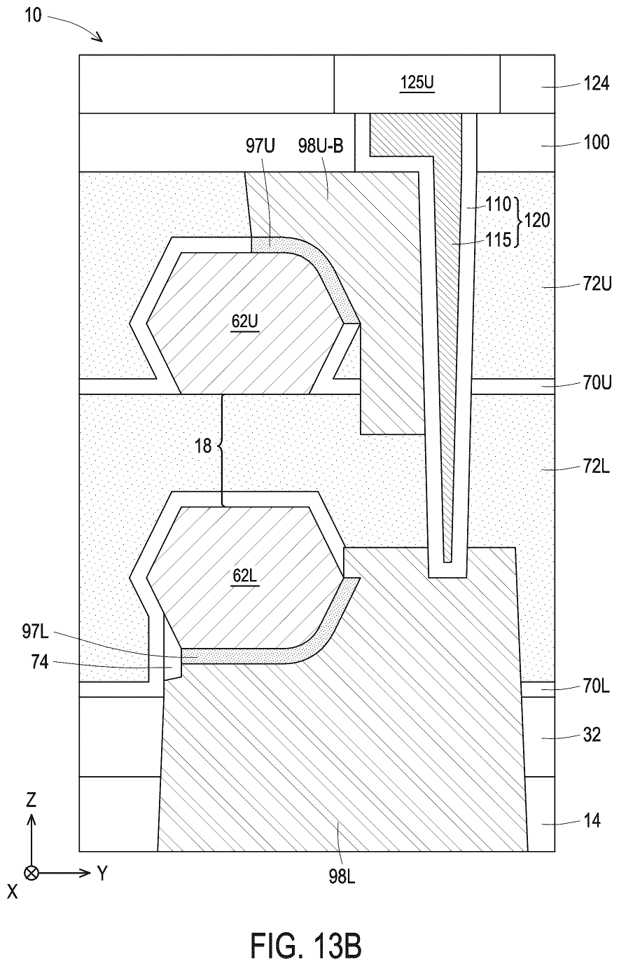

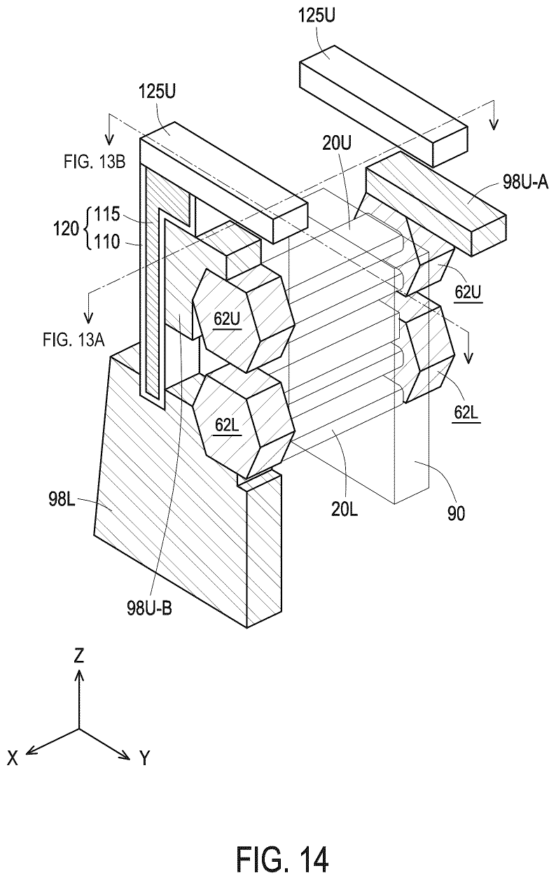

FIG. 2 is a flow chart of a method 200, in portion or entirety, for fabricating a device-level interconnect structure for a stacked device structure, such as stacked device structure 10, according to various aspects of the present disclosure. FIGS. 3A-13A and FIGS. 3B-13B are cross-sectional views of a stacked device structure, such as stacked device structure 10, in portion or entirety, at various fabrication stages associated with method 200 of FIG. 2 according to various aspects of the present disclosure. The cross-sectional views of FIGS. 3A-13A and FIGS. 3B-13B are taken (cut) along a gate widthwise direction (e.g., an x-direction) and a gate lengthwise direction (e.g., a y-direction), respectively, and thus, the cross-sectional views may be referred to as x-cut views and y-cut views, respectively. FIG. 14 is a perspective view of stacked device structure 10, in portion or entirety, at the fabrication stage associated with FIG. 13A and FIG. 13B according to various aspects of the present disclosure. FIG. 2, FIGS. 3A-13A, FIGS. 3B-13B, and FIG. 14 are discussed concurrently herein for ease of description and understanding. FIG. 2, FIGS. 3A-13A, FIGS. 3B-13B, and FIG. 14 have been simplified for the sake of clarity to better understand the inventive concepts of the present disclosure. Additional steps can be provided before, during, and after method 200, and some of the steps described can be moved, replaced, or eliminated for additional embodiments of method 200. Additional features can be added in stacked device structure 10 of FIGS. 3A-13A, FIGS. 3B-13B, and FIG. 14, and some of the features described below can be replaced, modified, or eliminated in other embodiments of stacked device structure 10 of FIGS. 3A-13A, FIGS. 3B-13B, and FIG. 14.

Referring to FIG. 2, FIG. 3A, and FIG. 3B, method 200 at block 205 includes forming an upper source/drain contact opening that exposes an upper source/drain. For example, a patterning process is performed on a dielectric layer (e.g., ILD layer 72U, CESL 70U, ILD layer 72L, or a combination thereof) to form an upper source/drain contact opening, such as a source/drain contact opening 94A and a source/drain contact opening 94B. Source/drain contact opening 94A and source/drain contact opening 94B extend through the dielectric layer and expose respective upper epitaxial source/drains 62U. In FIG. 3B, source/drain contact opening 94B extends through the dielectric layer to a depth D1, and source/drain contact opening 94B exposes a top and a sidewall of epitaxial source/drain 62U (e.g., at least two facets thereof). Source/drain contact opening 94B also extends below a bottom of epitaxial source/drain 62U. For example, source/drain contact opening 94B extends a distance d1 below the bottom of epitaxial source/drain 62U (and below a top of insulation structure 18). A distance d2 is between a top of epitaxial source/drain 62L and a bottom of source/drain contact opening 94B. In such embodiments, depth D1 is greater than a sum of a thickness of ILD layer 72U and a thickness of CESL 70U. In some embodiments, source/drain contact opening 94B extends below a top but not a bottom of epitaxial source/drain 62U. For example, source/drain contact opening 94B may extend through ILD layer 72U to and/or into CESL 70U. Source/drain contact opening 94A may be configured the same or differently than source/drain contact opening 94B.

The dielectric layer may be patterned by a lithography process and an etching process. The lithography process may include forming a patterned mask layer 95 over ILD layer 72U. Patterned mask layer 95 has openings 96 therein, each of which overlaps a respective epitaxial source/drain 62U. The etching process may include transferring a pattern in patterned mask layer 95 to the dielectric layer, for example, by removing portions of ILD layer 72U, CESL 70U, and ILD layer 72L exposed by openings 96. The etching process is a dry etch, a wet etch, other suitable etching process, or a combination thereof. The etching process selectively removes the dielectric layer (i.e., dielectric material(s)) with respect to epitaxial source/drains 62U (e.g., semiconductor material(s)). In some embodiments, the etching process removes patterned mask layer 95, in portion or entirety, from over the dielectric layer. In some embodiments, after the etching process, patterned mask layer 95 is removed from over the dielectric layer, for example, by an etching process and/or a resist stripping process.

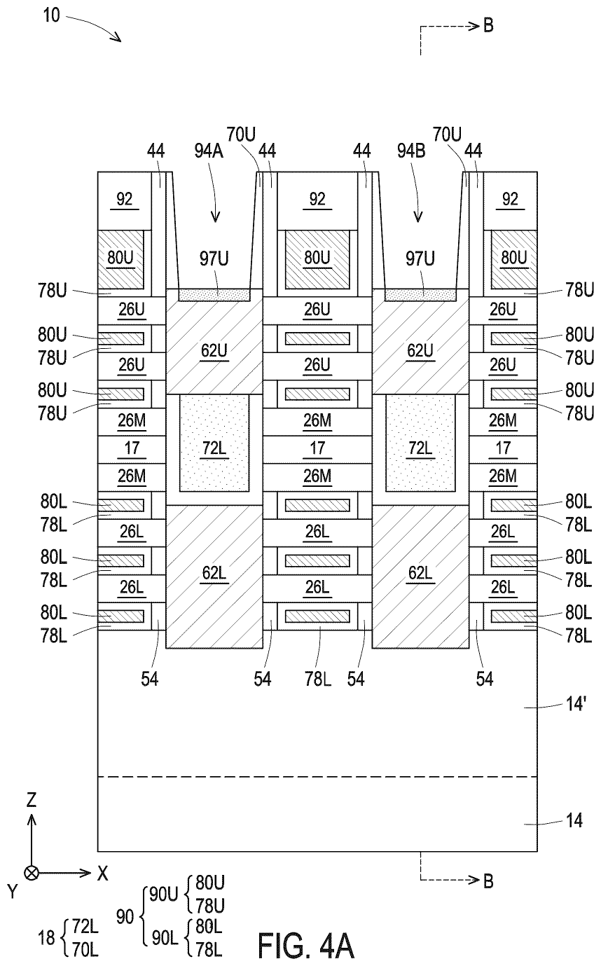

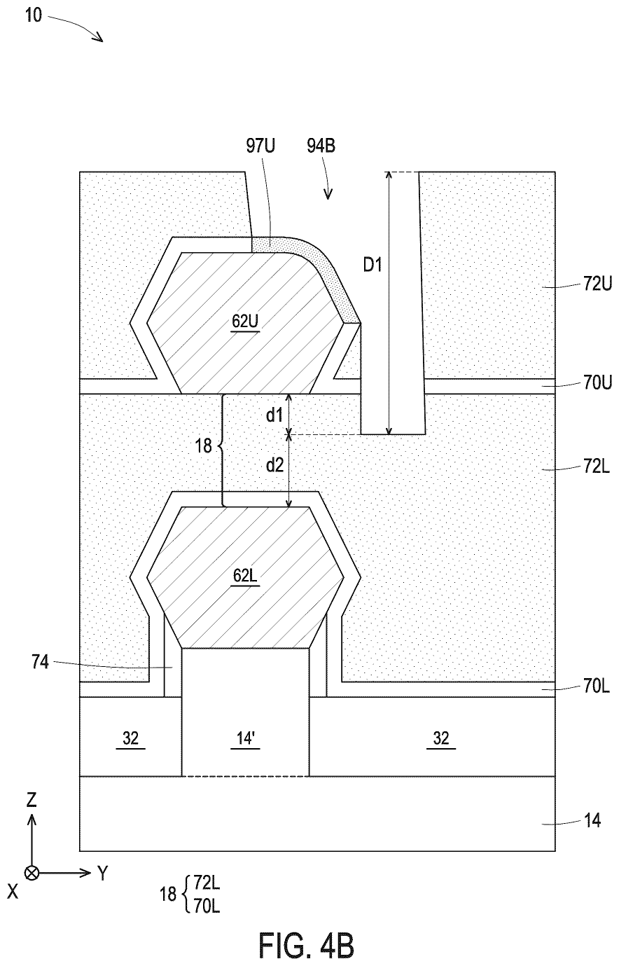

Referring to FIG. 4A and FIG. 4B, a silicidation process is performed to form upper silicide layers 97U over epitaxial source/drains 62U. In FIG. 4B, upper silicide layer 97U is disposed on a top and a sidewall of epitaxial source/drain 62U (e.g., on at least two facets thereof), and silicide layer 97U has a curvilinear profile. The silicidation process may include depositing a metal layer over epitaxial source/drains 62U by a suitable deposition process and heating stacked device structure 10 (for example, by subjecting it to an annealing process) to cause constituents of epitaxial source/drains 62U to react with metal constituents in the metal layer. In some embodiments, the silicidation process consumes and converts portions of epitaxial source/drains 62U into silicide layers 97U. The metal layer includes any metal constituent suitable for promoting silicide formation, such as nickel, platinum, palladium, vanadium, titanium, cobalt, tantalum, ytterbium, zirconium, other suitable metal, or a combination thereof. Silicide layers 97U thus include a metal constituent and a constituent of epitaxial source/drains 62U (for example, silicon and/or germanium). In some embodiments, the metal layer is a titanium-containing layer, and upper silicide layers 97U include titanium and silicon and can be referred to as a titanium silicide layers. Any un-reacted metal, such as remaining portions of the metal layer, is selectively removed by any suitable process.

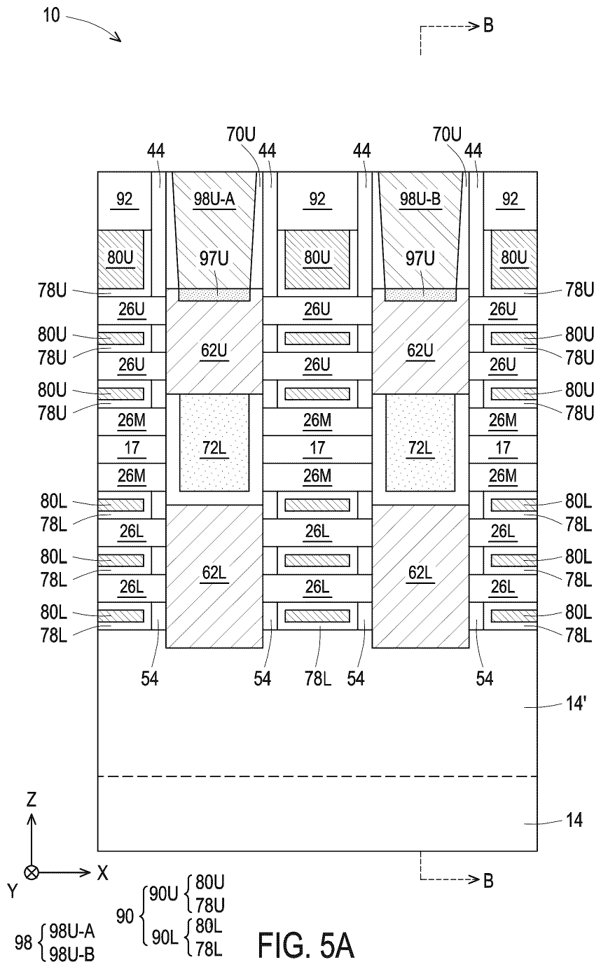

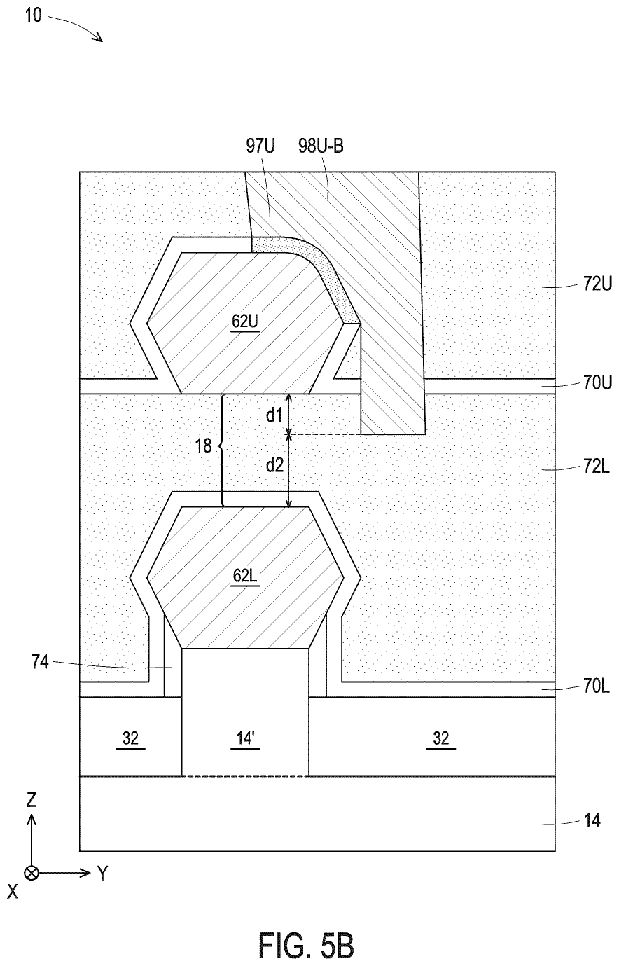

Referring to FIG. 2, FIG. 5A, and FIG. 5B, method 200 at block 210 includes forming an upper source/drain contact in the upper source/drain contact opening. For example, an upper source/drain contact 98U-A is formed in upper source/drain contact opening 94A and an upper source/drain contact 98U-B is formed in upper source/drain contact opening 94B. Source/drain contact 98U-A and source/drain contact 98U-B are formed over silicide layers 97U. In FIG. 5B, upper source/drain contact 98U-B extends through ILD layer 72U and CESL 70U, and upper source/drain contact 98U-B is disposed on a top and a sidewall of upper epitaxial source/drain 62U (e.g., on at least two facets thereof). Further, source/drain contact 98U-B extends distance d1 below the bottom of epitaxial source/drain 62U, and distance d2 is between the top of epitaxial source/drain 62L and a bottom of source/drain contact 98U-B. In such embodiments, a thickness of upper source/drain contact 98U-B (e.g., along the z-direction) is greater than a sum of a thickness of ILD layer 72U and a thickness of CESL 70U. Further, upper source/drain contact 98U-B has a generally L-shaped profile with a horizontal portion/extension (e.g., along the y-direction) and a vertical portion/extension (e.g., along the z-direction). In some embodiments, upper source/drain contact 98U-B extends below a top but not the bottom of epitaxial source/drain 62U, such as through ILD layer 72U to and/or into CESL 70U.

Source/drain contact 98U-A and source/drain contact 98U-B are collectively referred to as upper source/drain contacts 98U. Upper source/drain contacts 98U include an electrically conductive material, such as tungsten, ruthenium, cobalt, molybdenum, copper, aluminum, titanium, tantalum, iridium, palladium, platinum, nickel, tin, gold, silver, other suitable metal, alloys thereof, or a combination thereof. In the depicted embodiment, upper source/drain contacts 98U are barrier-free/liner-free metal plugs, such as tungsten plugs, cobalt plugs, or ruthenium plugs. For example, upper source/drain contacts 98U each include a metal bulk layer, such as a tungsten plug, that physically, directly contacts surrounding dielectric materials, such as ILD layer 72U, CESL 70U, and ILD layer 72L. In some embodiments, upper source/drain contacts 98U include metal bulk layers and metal liner(s), where the metal liner(s) is between the metal bulk layers and surrounding dielectric materials. In some embodiments, the metal liner(s) is between the metal bulk layers and upper silicide layers 97U.

In some embodiments, forming upper source/drain contacts 98U includes depositing at least one electrically conductive material (e.g., a metal bulk material) over ILD layer 72U that fills source/drain contact opening 94A and source/drain contact opening 94B and performing a planarization process (e.g., chemical mechanical polishing (CMP)) to remove portions of the at least one electrically conductive material that are disposed over the top of ILD layer 72U, hard masks 92, gate spacers 44, or a combination thereof. The planarization process may be performed until reaching and exposing ILD layer 72U. Remainders of the electrically conductive material form metal plugs and, in some embodiments, metal liners. In some embodiments, ILD layer 72U, hard masks 92, gate spacers 44, contact spacers, or a combination thereof function as a planarization stop layer. In some embodiments, one or more insulation layers may be deposited in source/drain contact opening 94A and source/drain contact opening 94B and processed to form contact spacers, such as dielectric layers and/or air gaps, along sidewalls of the electrically conductive portions of upper source/drain contacts 98U.

In some embodiments, a blanket deposition process (e.g., blanket chemical vapor deposition (CVD)) forms a metal bulk material (e.g., tungsten) over ILD layer 72U that fills source/drain contact opening 94A and source/drain contact opening 94B. The blanket deposition process may include flowing a metal-containing precursor (e.g., a tungsten-containing precursor, such as WF₆ and/or WCl₅) and a reactant precursor (e.g., H₂, other suitable reactant gas, or a combination thereof) into a process chamber. In some embodiments, a carrier gas is used to deliver the metal-containing precursor gas and/or the reactant gas to the process chamber. The carrier gas may be an inert gas, such as an argon-containing gas, a helium-containing gas, a xenon-containing gas, other suitable inert gas, or a combination thereof. In some embodiments, the blanket deposition process is physical vapor deposition (PVD), atomic layer deposition (ALD), other process, or a combination thereof.

In some embodiments, a bottom-up deposition process fills source/drain contact opening 94A and source/drain contact opening 94B with a metal bulk material (e.g., tungsten) from bottom to top. The bottom-up deposition process, such as selective CVD or selective ALD, may include flowing a metal-containing precursor (e.g., a tungsten-containing precursor, such as WF₆ and/or WCl₅), a reactant precursor (e.g., H₂, other suitable reactant gas, or a combination thereof), and a carrier gas into a process chamber and tuning deposition parameters to selectively grow the metal bulk material from silicide layers 97U, metal seed layers, metal liner(s) formed before the metal bulk material, or a combination thereof while limiting growth of the metal bulk material from dielectric materials (e.g., ILD layer 72U, CESL 70U, ILD layer 72L, contact spacers, or a combination thereof). The deposition parameters may include deposition precursors (e.g., metal precursors and/or reactants), deposition precursor flow rates, deposition temperature, deposition time, deposition pressure, source power, RF bias voltage, RF bias power, other suitable deposition parameters, or a combination thereof. In some embodiments, the bottom-up deposition process includes multiple deposition/etch cycles, each of which can include depositing a conductive material and etching back the conductive material successively.

In embodiments where upper source/drain contacts 98U include metal liner(s), a deposition process forms a barrier/liner material over ILD layer 72U, CESL 70U, ILD layer 72L, and silicide layers 97U before forming the metal bulk material. The barrier/liner material partially fills and lines source/drain contact opening 94A and source/drain contact opening 94B. The barrier/liner material can promote adhesion between dielectric materials and metal bulk layers of upper source/drain contacts 98U and/or prevent diffusion of metal constituents from the metal bulk layers into surrounding dielectric materials. In some embodiments, the barrier/liner material includes tantalum, tantalum nitride, tantalum aluminum nitride, tantalum silicon nitride, tantalum carbide, titanium, titanium nitride, titanium silicon nitride, titanium aluminum nitride, titanium carbide, tungsten, tungsten nitride, tungsten carbide, molybdenum nitride, cobalt, cobalt nitride, ruthenium, palladium, or a combination thereof.

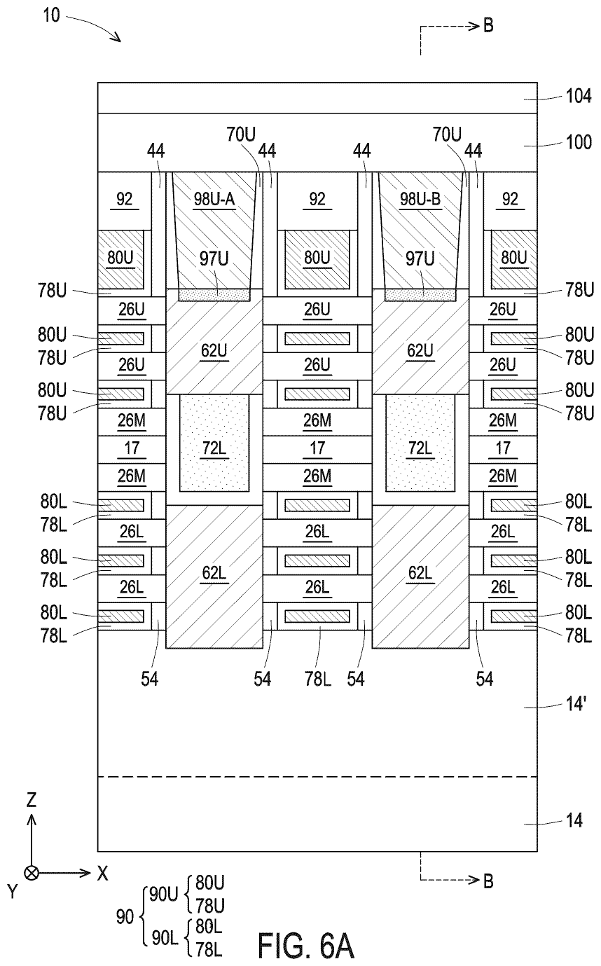

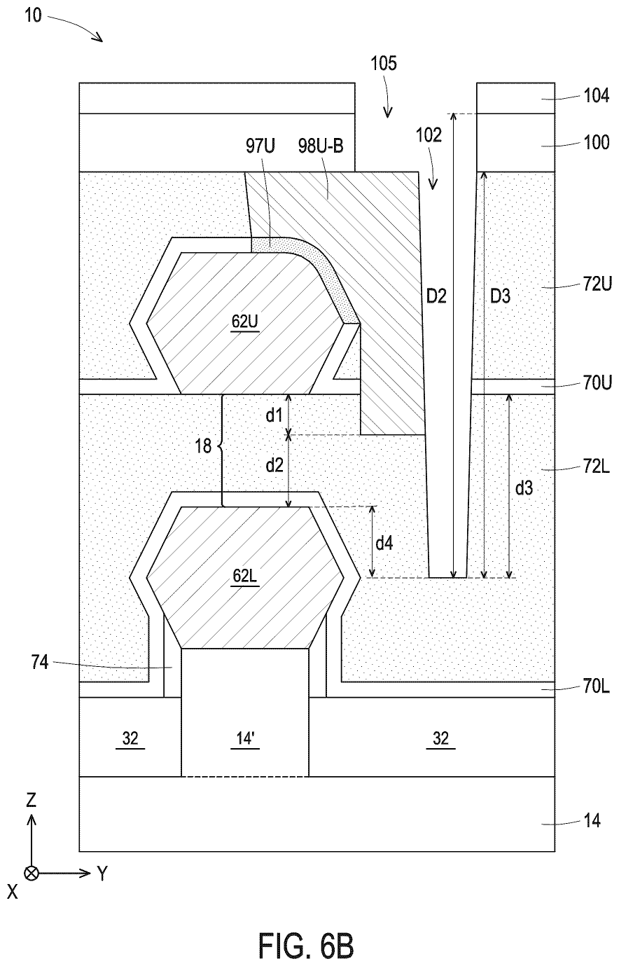

Referring to FIG. 2, FIG. 6A, and FIG. 6B, method 200 at block 215 includes forming a source/drain via opening that exposes the upper source/drain contact and extends below the upper source/drain. For example, a patterning process is performed on a dielectric layer (e.g., a dielectric layer 100, ILD layer 72U, CESL 70U, ILD layer 72L, or a combination thereof) to form an upper source/drain via opening 102. Source/drain via opening 102 extends through the dielectric layer to a depth D2 and exposes upper source/drain contact 98U-B. In FIG. 6B, source/drain via 102 has a first sidewall formed by dielectric layer 100, ILD layer 72U, CESL 70U, and ILD layer 72L; a second sidewall formed by source/drain contact 98U-B and ILD layer 72L; a first bottom formed by ILD layer 72L; a second bottom formed by a top of source/drain contact 98U-B; and a third sidewall formed by dielectric layer 100. In such embodiments, source/drain via opening 102 has a generally L-shaped profile with a horizontal portion/extension in dielectric layer 100, which exposes a top of source/drain contact 98U-B and extends laterally beyond and overlaps a sidewall of source/drain contact 98U-B, and a vertical portion/extension in ILD layer 72U, CESL 70U, and ILD layer 72L, which exposes the sidewall of source/drain contact 98U-B. The vertical portion/extension has a depth D3, which is between a top of ILD layer 72U and a bottom of source/drain via opening 102, that is greater than depth D1, which is between the top of ILD layer 72U and a bottom of source/drain contact opening 94B (and source/drain contact 98U-B). Source/drain via opening 102 extends below the bottom of epitaxial source/drain 62U, and in the depicted embodiment, below the top of epitaxial source/drain 62L. For example, source/drain via opening 102 extends a distance d3 below the bottom of epitaxial source/drain 62U (and below a top of insulation structure 18) and a distance d4 below the top of epitaxial source/drain 62L. Source/drain via opening 102 also extends below a bottom of source/drain contact 98U-B. For example, a distance between the bottom of source/drain contact 98U-B and a bottom of source/drain contact opening 102 is a sum of distance d2 and distance d4. In such embodiments, depth D2 is greater than a sum of a thickness of dielectric layer 100, a thickness of ILD layer 72U, a thickness of CESL 70U, and distance d1. In some embodiments, source/drain via opening 102 extends below a bottom of source/drain contact 98U-B but not below the top of epitaxial source/drain 62L.

The dielectric layer may be patterned by a lithography process and an etching process. The lithography process may include forming a patterned mask layer 104 over dielectric layer 100. Patterned mask layer 104 has an opening 105 therein that overlaps a top of source/drain contact 98U-B and a portion of a dielectric layer that is adjacent to a sidewall of source/drain contact 98U-B. The etching process may include transferring a pattern in patterned mask layer 104 to the dielectric layer, for example, by removing portions of dielectric layer 100, ILD layer 72U, CESL 70U, and ILD layer 72L exposed by opening 105. The etching process is a dry etch, a wet etch, other suitable etching process, or a combination thereof. The etching process selectively removes the dielectric layer (i.e., dielectric material(s)) with respect to source/drain contact 98U-B (e.g., metal material(s)). In some embodiments, the etching process removes patterned mask layer 104, in portion or entirety, from over dielectric layer 100. In some embodiments, after the etching process, patterned mask layer 104 is removed from over the dielectric layer 100, for example, by an etching process and/or a resist stripping process.

In the depicted embodiment, dielectric layer 100 is an ILD layer, which may be configured and/or formed similar to ILD layer 72U and/or ILD layer 72L. For example, dielectric layer 100 includes a dielectric material such as described above with reference to ILD layer 72U and/or ILD layer 72L. The dielectric material may be the same or different than a dielectric material of ILD layer 72U and/or a dielectric material of ILD layer 72L. In some embodiments, dielectric layer 100 is a low-k dielectric layer, such as a silicon oxide layer or a silicon oxycarbide layer having a low dielectric constant. In some embodiments, dielectric layer 100 has a multilayer structure, such as an ILD layer over a CESL, which may be similar to CESL 70U and/or CESL 70L. Forming dielectric layer 100 may include one or more deposition processes and a CMP process and/or other planarization process. The deposition process(es) can include CVD, PVD, ALD, high density plasma CVD (HDPCVD), metal organic CVD (MOCVD), remote plasma CVD (RPCVD), plasma enhanced CVD (PECVD), low pressure CVD (LPCVD), atomic layer CVD (ALCVD), atmospheric pressure CVD (APCVD), plasma enhanced ALD (PEALD), other suitable method, or combinations thereof.

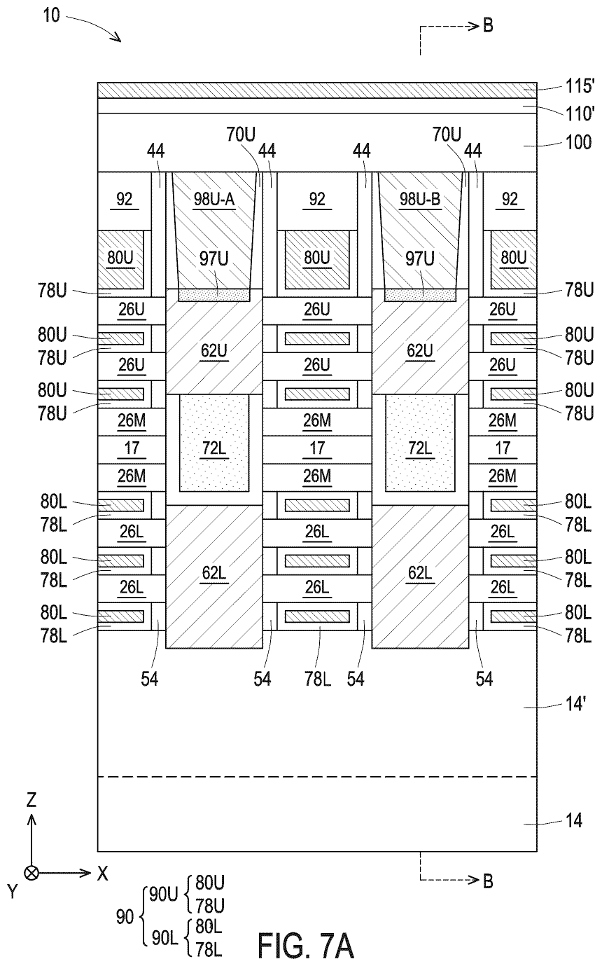

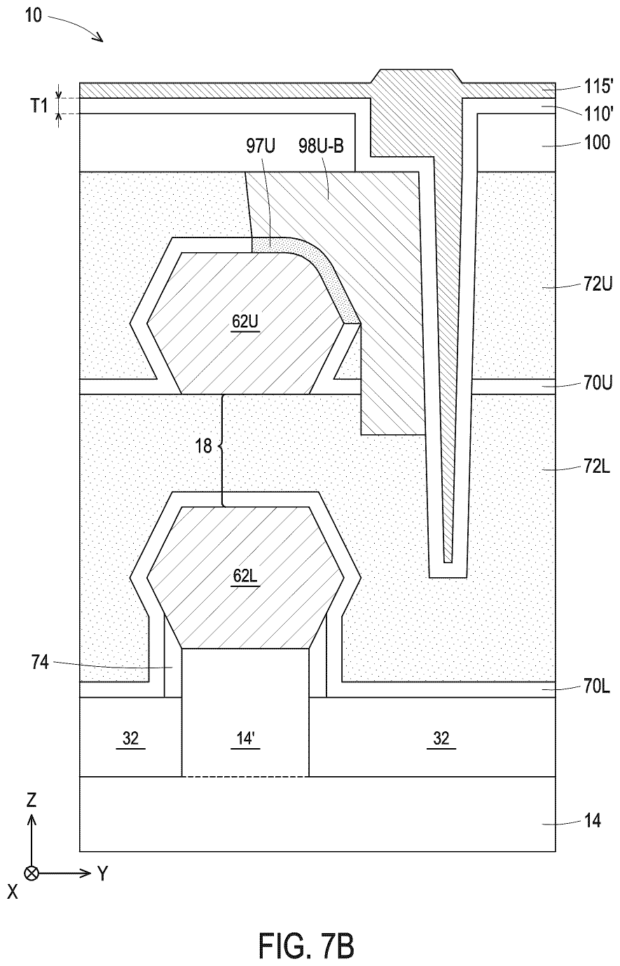

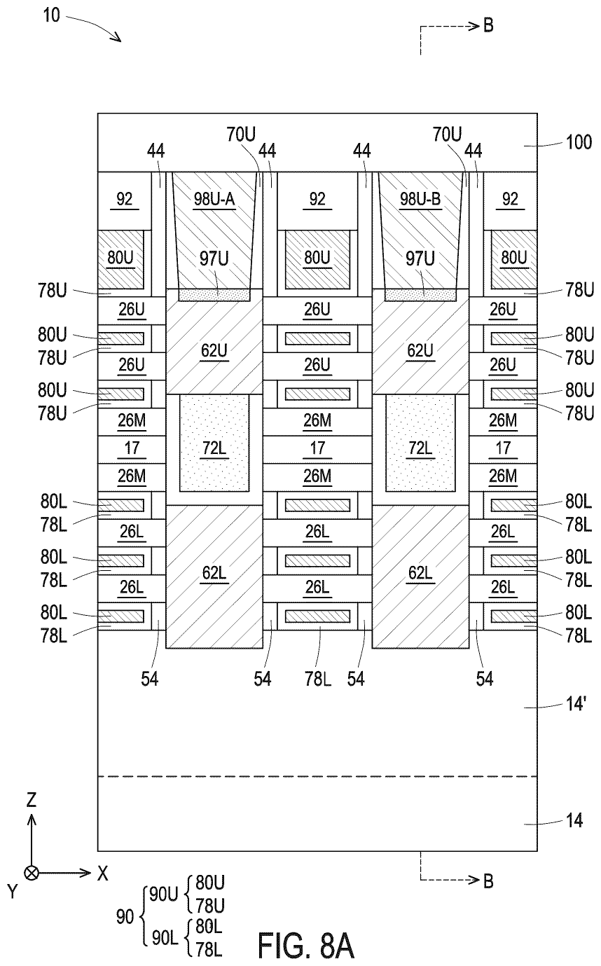

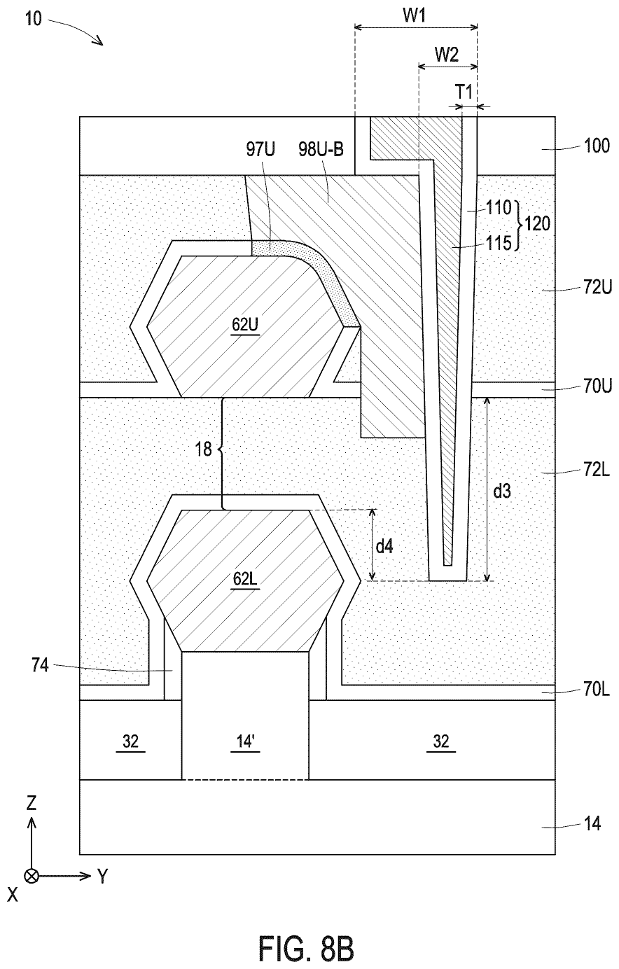

Referring to FIG. 2, FIG. 7A, FIG. 7B, FIG. 8A, and FIG. 8B, method 200 at block 220 includes forming a source/drain via that includes ruthenium and aluminum in the source/drain via opening. For example, in FIG. 7A and FIG. 7B, a via liner/barrier layer 110′ and a via bulk layer 115′ are formed in source/drain via opening 102. Via liner layer 110′ partially fills source/drain via opening 102, and via bulk layer 115′ fills a remainder of source/drain via opening 102. In FIG. 7B, via liner layer 110′ covers surfaces of stacked device structure 10 that form source/drain via opening 102. For example, via liner layer 110′ is disposed on dielectric layer 100, ILD layer 72U, source/drain contact 98U-B (e.g., a top and sidewall thereof), CESL 70U, and ILD layer 72L. Via liner layer 110′ is further disposed on a top surface of dielectric layer 100. Via bulk layer 115′ is disposed over via liner layer 110′, and via liner layer 110′ is disposed between via bulk layer 115′ and dielectric layer 100, ILD layer 72U, source/drain contact 98U-B, CESL 70U, and ILD layer 72L. Via liner layer 110′ and via bulk layer 115′ are formed by PVD, CVD, ALD, electroplating, electroless plating, other suitable deposition process, or a combination thereof. In the depicted embodiment, via liner layer 110′ and via bulk layer 115′ are formed by different types of deposition processes. For example, via liner layer 110′ (e.g., an aluminum-comprising layer) is formed by PVD, and via bulk layer 115′ (e.g., a ruthenium-comprising layer) is formed by CVD. In some embodiments, via liner layer 110′ and via bulk layer 115′ are formed by a same deposition process type.

Via liner layer 110′ is an aluminum-comprising layer having a thickness T1. In some embodiments, via liner layer 110′ is an aluminum layer. In some embodiments, via liner layer 110′ is an aluminum alloy layer. For example, via liner layer 110′ includes aluminum and ruthenium, and via liner layer 110′ is a ruthenium aluminide layer. In some embodiments, via liner layer 110′ has a multilayer structure. For example, via liner layer 110′ may include a first sublayer (e.g., an aluminum layer) and a second sublayer thereover (e.g., a ruthenium aluminide layer or a ruthenium layer). The first sublayer and the second sublayer may be formed by PVD and CVD, respectively. In some embodiments, via liner layer 110′ is conformally deposited and a thickness of via liner layer 110′ is conformal over surfaces forming source/drain via opening 102 (i.e., thickness T1 is substantially uniform along the first sidewall, the second sidewall, the third sidewall, the first bottom, and the second bottom of source/drain via opening 102).

Via bulk layer 115′ is a ruthenium-comprising layer. In some embodiments, via bulk layer 115′ is a ruthenium layer. In some embodiments, via bulk layer 115′ is a ruthenium alloy layer. For example, via bulk layer 115′ includes ruthenium and aluminum, and via bulk layer 115′ is a ruthenium aluminide layer. In some embodiments, via bulk layer 115′ has a multilayer structure. For example, via bulk layer 115′ may include a first sublayer (e.g., a ruthenium aluminide layer or a ruthenium layer) and a second sublayer (e.g., a ruthenium layer or a ruthenium aluminide layer). In such embodiments, the first sublayer may be a liner, and the second sublayer may be a bulk layer wrapped by the first sublayer. In some embodiments, via bulk layer 115′ is formed by a blanket deposition process. In some embodiments, via bulk layer 115′ is formed by a selective deposition process, such as a bottom-up deposition process.

In FIG. 8A and FIG. 8B, a planarization process (e.g., CMP) is performed to remove excess via liner layer 110′ and/or via bulk layer 115′, such as that disposed over the top surface of dielectric layer 100. A remainder of via liner layer 110′ and a remainder of via bulk layer 115′ form a via liner 110 and a via plug 115, respectively, of a source/drain via 120. In some embodiments, dielectric layer 100 functions as a planarization stop layer. The planarization process can planarize a top surface of source/drain via 120, such that the top surface of dielectric layer 100 and the top surface of source/drain via 120 form a substantially planar surface.

Processing associated with forming source/drain contact 98U-A, source/drain contact 98U-B, and source/drain via 120 may generally be referred to as MOL processing. In some embodiments, MOL fabricates device-level interconnects (also referred to as MOL interconnect structures), each of which can include a device-level contact and a local contact. The device-level interconnect (e.g., source/drain contact) connects an electrically active feature of an IC device (e.g., a source/drain of a transistor) to a local contact (e.g., a source/drain via), and the local contact connects the device-level contact to a BEOL feature, such as a first metallization layer thereof. In the depicted embodiment, source/drain contact 98U-B and source/drain via 120 form a device-level interconnect, source/drain contact 98U-B may be referred to as a device-level contact, and source/drain via 120 may be referred to as a local contact. Source/drain contact 98U-B (device-level contact) connects epitaxial source/drain 62U to source/drain via 120 (local contact), and source/drain via 120 connects source/drain contact 98U-B to a first metallization layer of a multilayer interconnect (MLI) feature.

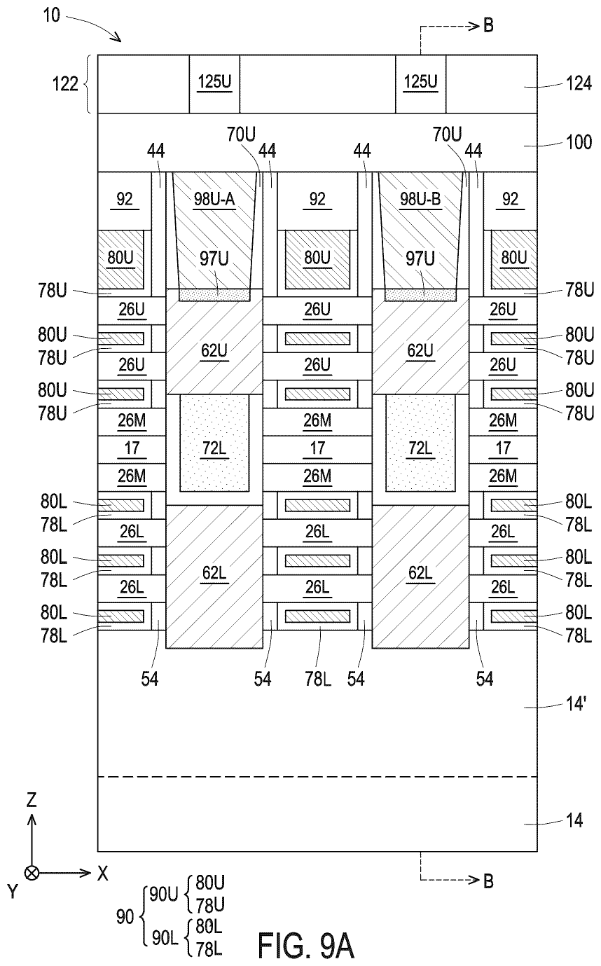

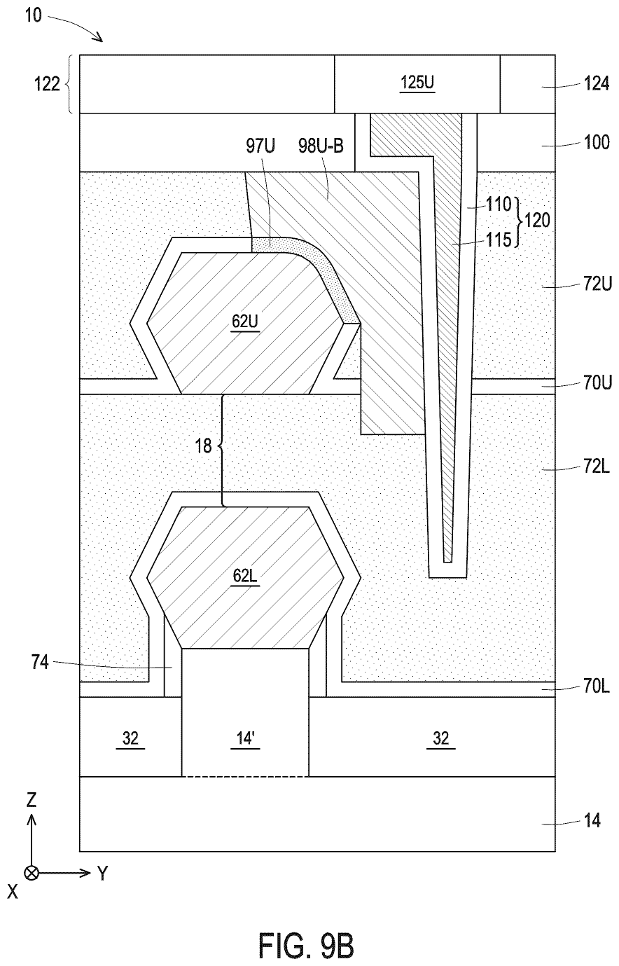

Referring to FIG. 9A and FIG. 9B, method 200 may include frontside BEOL processing to form metallization layers of an MLI feature 122 over dielectric layer 100. MLI feature 122 electrically connects devices (for example, transistors, resistors, capacitors, inductors, etc.), components of devices (for example, gates and/or source/drains), devices within MLI feature 122, components of MLI feature 122, or a combination thereof, such that the devices and/or components can operate as specified by design requirements. The metallization layers can route signals between the devices and/or the components thereof and/or distribute signals (e.g., clock signals, voltage signals, ground signals, other signals, or a combination thereof) to the devices and/or the components thereof. In some embodiments, a metallization layer/level includes at least one interconnect structure disposed in an insulator layer, such as a metal line and a via disposed in a dielectric layer, where the via connects the metal line to a metal line of an interconnect in a different metallization layer.

In FIG. 9A and FIG. 9B, forming the first metallization layer/level includes forming a dielectric layer 124 over dielectric layer 100, patterning dielectric layer 124 to forming openings therein (such as an opening therein that exposes source/drain via 120), and forming metal lines 125U (e.g., electrically conductive material(s)) in the openings. Metal lines of the first metallization layer can collectively be referred to as a metal one (M1) layer (and individually referred to as M1 metal lines). In some embodiments, the first metallization layer includes vias that physically and/or electrically connect local contacts (e.g., source/drain via 120) to metal lines (e.g., metal lines 125U). In such embodiments, the vias of the first metallization layer can collectively be referred to as a via zero (V0) layer (and individually referred to as V0 vias). In such embodiments, the V0 layer is a bottommost via layer of the MLI feature.

Frontside BEOL processing may continue with forming additional metallization layers (levels) of MLI feature 122 over the first metallization layer. For example, BEOL processing may include forming a second metallization layer (i.e., a metal two (M2) layer and a via one (V1) layer), a third metallization layer (i.e., a metal three (M3) layer and a via two (V2) layer), a fourth metallization layer (i.e., a metal four (M4) layer and a via three (V3) layer), a fifth metallization layer (i.e., a metal five (M5) layer and a via four (V4) layer), a sixth metallization layer (i.e., a metal six (M6) layer and a via five (V5) layer), a seventh metallization layer (i.e., a metal seven (M7) layer and a via six (V6) layer) to a topmost metallization layer (i.e., a metal X (MX) layer and a via Y (VY) layer, where X is a total number of patterned metal line layers of the MLI feature and Y is a total number of patterned via layers of the MLI feature) over the first metallization layer. Each of the metallization layers may include a patterned metal line layer and a patterned via layer configured to provide at least one BEOL interconnect structure disposed in an insulator layer, which may include at least one ILD layer and at least one CESL. MLI feature 122 may have any number of metal layers, via layers, dielectric layers, or a combination thereof depending on design requirements of stacked device structure 10.

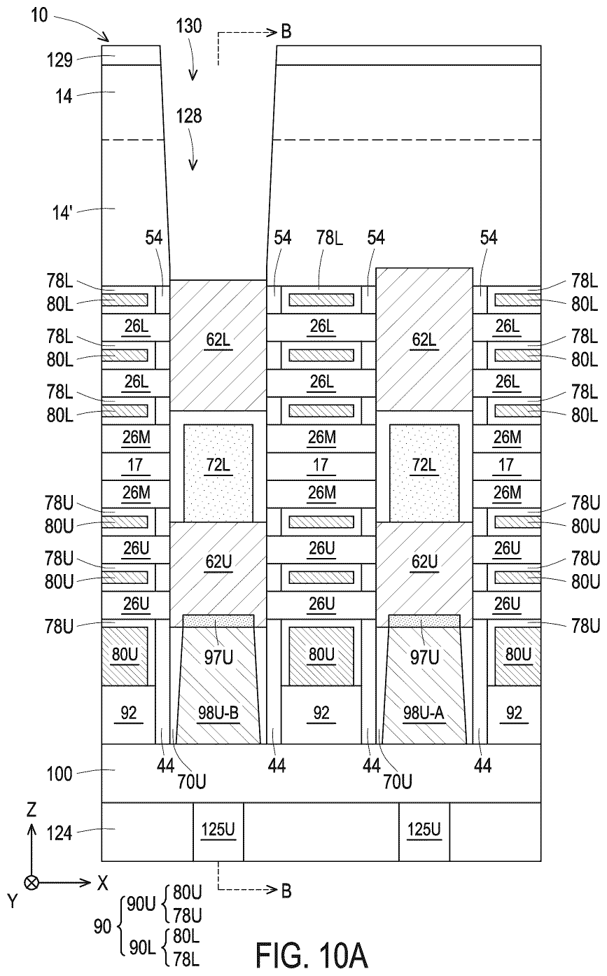

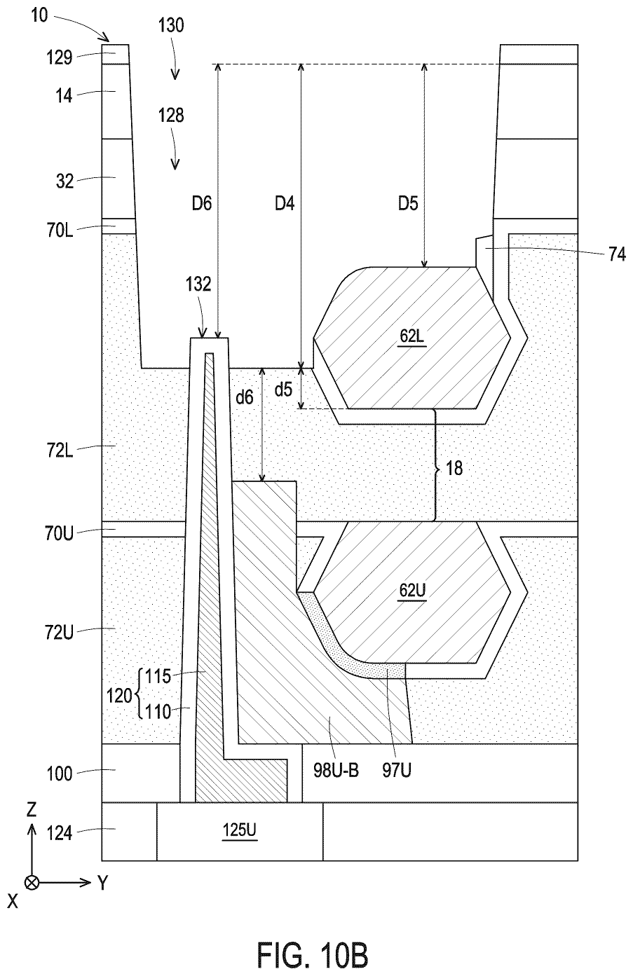

Referring to FIG. 2, FIG. 10A, and FIG. 10B, method 200 at block 225 includes forming a lower source/drain contact opening that exposes a lower source/drain and the source/drain via. For example, a patterning process is performed on a backside of stacked device structure 10 to form a source/drain contact opening 128 that exposes source/drain via 120 and lower epitaxial source/drain 62L. In FIG. 10A and FIG. 10B, the patterning process may be performed on substrate 14, isolation features 32, CESL 70L, ILD layer 72L, or a combination thereof. In FIG. 10B, source/drain contact opening 128 extends through substrate 14 (including mesa 14′), isolation features 32, CESL 70L, and into ILD layer 72L. Source/drain contact opening 128 extends to a depth D4, exposes a bottom and a sidewall of lower epitaxial source/drain 62L (e.g., at least two facets thereof), and exposes a bottom portion 132 of source/drain via 120. A depth D5 is between the backside of substrate 14 and the bottom of epitaxial source/drain 62L, and a depth D6 is between the backside of substrate 14 and a bottom of source/drain via 120. To ensure that epitaxial source/drain 62L and source/drain via 120 are exposed by source/drain contact opening 128, depth D4 is greater than or equal to the greater of depth D5 or depth D6. For example, since depth D6 is greater than depth D5, depth D4 is greater than or equal to depth D6. In the depicted embodiment, since depth D4 is greater than depth D6, source/drain contact opening 128 exposes the bottom of source/drain via 120 and portions of the sidewalls of source/drain via 120. Further, in FIG. 10B, source/drain contact opening 128 extends below the bottom but not a top of epitaxial source/drain 62L. A distance d5 is between the top of epitaxial source/drain 62L and a bottom of source/drain contact opening 128, and a distance d6 is between the bottom of source/drain contact opening 128 and a bottom of source/drain contact 98U-B. In some embodiments, source/drain contact opening 128 extends below the top of epitaxial source/drain 62L but not to the bottom of source/drain contact 98U-B. In some embodiments, source/drain contact opening 128 does not extend beyond the bottom of source/drain via 120. In some embodiments, depth D4 is greater than a sum of a thickness of substrate 14, a thickness of isolation features 32, and a thickness of CESL 70L.

The backside of stacked device structure 10 may be patterned by a lithography process and an etching process. The lithography process may include forming a patterned mask layer 129 over a backside of substrate 14. Patterned mask layer 129 has an opening 130 therein that overlaps epitaxial source/drain 62L and source/drain via 120. The etching process may include transferring a pattern in patterned mask layer 129 to various layers covering epitaxial source/drain 62L and/or source/drain via 120 that are exposed by opening 130, such as substrate 14 (including mesa 14′), isolation features 32, CESL 70L, ILD layer 72L, or a combination thereof. The etching process is a dry etch, a wet etch, other suitable etching process, or a combination thereof. The etching process may be a multistep process, such as a first etch to selectively remove substrate 14 and a second etch to selectively remove isolation features 32, CESL 70L, ILD layer 72L, or a combination thereof. The first etch may selectively remove substrate 14 (i.e., semiconductor material(s)) with respect to isolation features 32, CESL 70L, ILD layer 72L, or a combination thereof (e.g., dielectric material(s)), and the second etch may selectively remove isolation features 32, CESL 70L, ILD layer 72L, or a combination thereof (i.e., dielectric material(s)) with respect to epitaxial source/drain 62L (e.g., semiconductor material(s)) and/or source/drain via 120 (e.g., metal material(s)). In some embodiments, patterning isolation features 32, CESL 70L, and ILD layer 72L may be a multistep etch process (e.g., using different etchants to pattern each layer). In some embodiments, the etching process removes patterned mask layer 129, in portion or entirety, from over substrate 14. In some embodiments, after the etching process, patterned mask layer 129 is removed from over substrate 14, for example, by an etching process and/or a resist stripping process.

In the depicted embodiment, processing includes flipping over stacked device structure 10 before forming source/drain contact opening 128, such that processing involved with forming source/drain contact opening 128 and forming a source/drain contact therein is performed on a backside of stacked device structure 10 (e.g., patterning layers and metal layers are formed over the backside of stacked device structure 10). In some embodiments, processing may include bonding and/or attaching a carrier wafer (not shown) to a frontside of stacked device structure 10. In some embodiments, stacked device structure 10 is bonded to the carrier wafer (also referred to as a carrier substrate) using dielectric-to-dielectric bonding. For example, bonding carrier wafer to stacked device structure 10 may include forming a first dielectric layer over the frontside of stacked device structure 10, forming a second dielectric layer over the carrier wafer, flipping over and placing the stacked device structure 10 over the carrier wafer, such that the second dielectric layer of the carrier wafer contacts the first dielectric layer of stacked device structure 10, and performing an anneal or other suitable process to bond the first dielectric layer and the second dielectric layer. In such embodiments, a bonding layer may be between the carrier wafer and stacked device structure 10, which may include the first dielectric layer, the second dielectric layer, a portion of the first dielectric layer, a portion of the second dielectric layer, a bonded portion of the first dielectric layer and the second dielectric layer, or a combination thereof. In some embodiments, the bonding layer is an oxide layer. In some embodiments, the carrier wafer includes silicon, soda-lime glass, fused silica, fused quartz, calcium fluoride, other suitable carrier wafer/substrate material, or a combination thereof.

In some embodiments, before forming source/drain contact opening 128, substrate 14 may be removed from stacked device structure 10 by CMP and/or other suitable planarization process, thereby exposing isolation features 32. The planarization process may stop upon reaching isolation features 32. In such embodiments, source/drain contact opening 128 extends through isolation features 32, CESL 70L, and into ILD layer 72L, and depth D4, depth D5, and depth D6 may be between tops of isolation features 32 and respective bottom features. In some embodiments, isolation features 32, mesas 14′, CESL 70L, or a combination thereof are removed from stacked device structure 10 by CMP and/or other suitable planarization process, thereby exposing epitaxial source/drain 62L. The planarization process may stop upon reaching epitaxial source/drain 62L. In such embodiments, source/drain contact opening 128 extends into ILD layer 72L, and source/drain contact opening 128 has depth D4 and depth D6, which may be between the bottom of epitaxial source/drain 62L and respective bottom features. In some embodiments, substrate 14 (including mesas 14′), isolation features 32, CESL 70L, or a combination thereof are removed by an etching process.

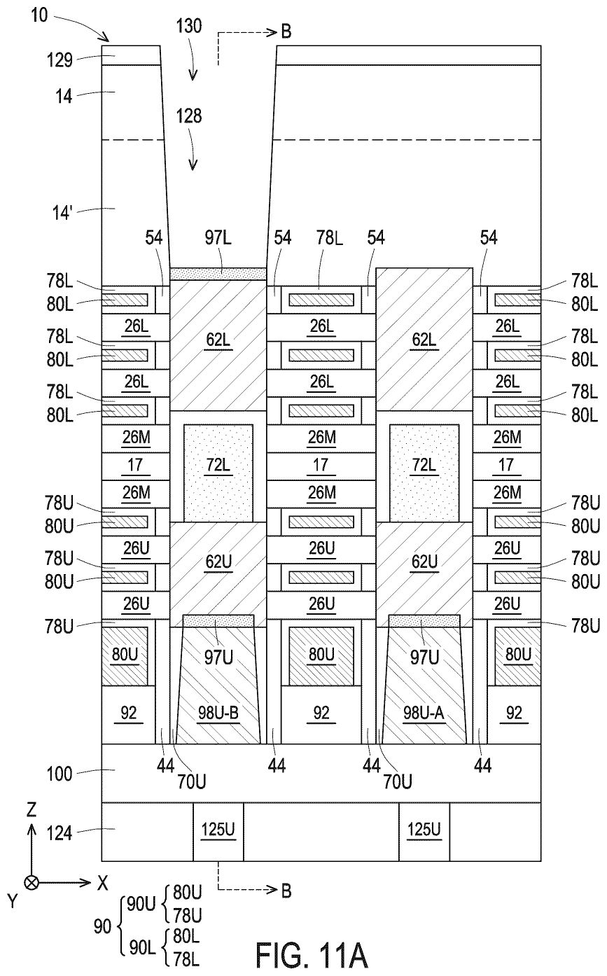

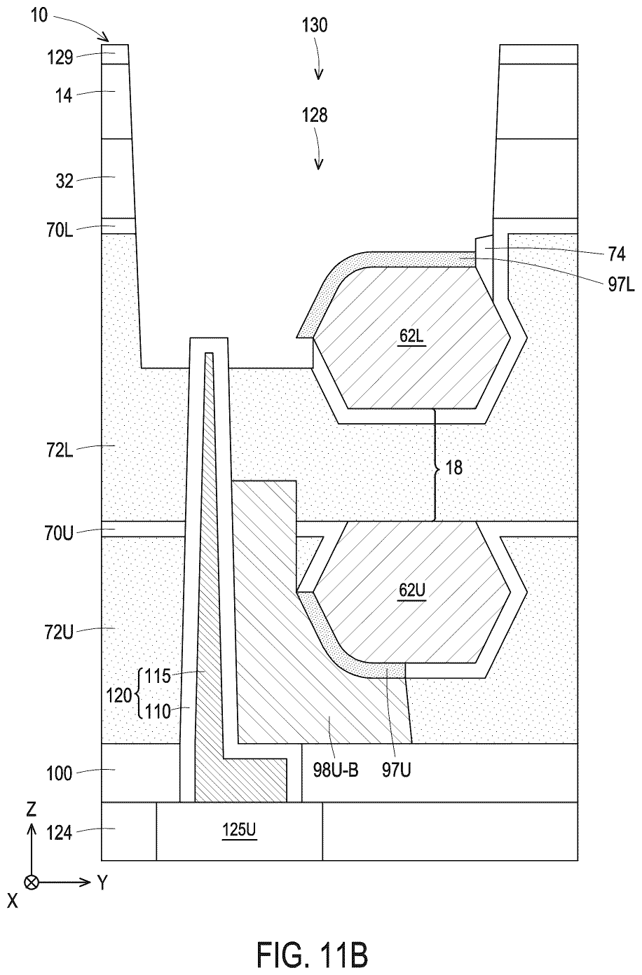

Referring to FIG. 11A and FIG. 11B, a silicidation process is performed to form lower silicide layers 97L over lower epitaxial source/drains 62L. In FIG. 11B, silicide layer 97L is disposed on a bottom and a sidewall of epitaxial source/drain 62L (e.g., on at least two facets thereof), and silicide layer 97L has a curvilinear profile. The silicidation process may include depositing a metal layer over epitaxial source/drains 62L by a suitable deposition process and heating stacked device structure 10 (for example, by subjecting it to an annealing process) to cause constituents of epitaxial source/drains 62L to react with metal constituents in the metal layer. In some embodiments, the silicidation process consumes and converts portions of epitaxial source/drains 62L into silicide layers 97L. The metal layer includes any metal constituent suitable for promoting silicide formation, such as nickel, platinum, palladium, vanadium, titanium, cobalt, tantalum, ytterbium, zirconium, other suitable metal, or a combination thereof. Silicide layers 97L thus include a metal constituent and a constituent of epitaxial source/drains 62L (for example, silicon and/or germanium). In some embodiments, the metal layer is a titanium-containing layer, and silicide layers 97L include titanium, silicon, and germanium. Any un-reacted metal is selectively removed by any suitable process.

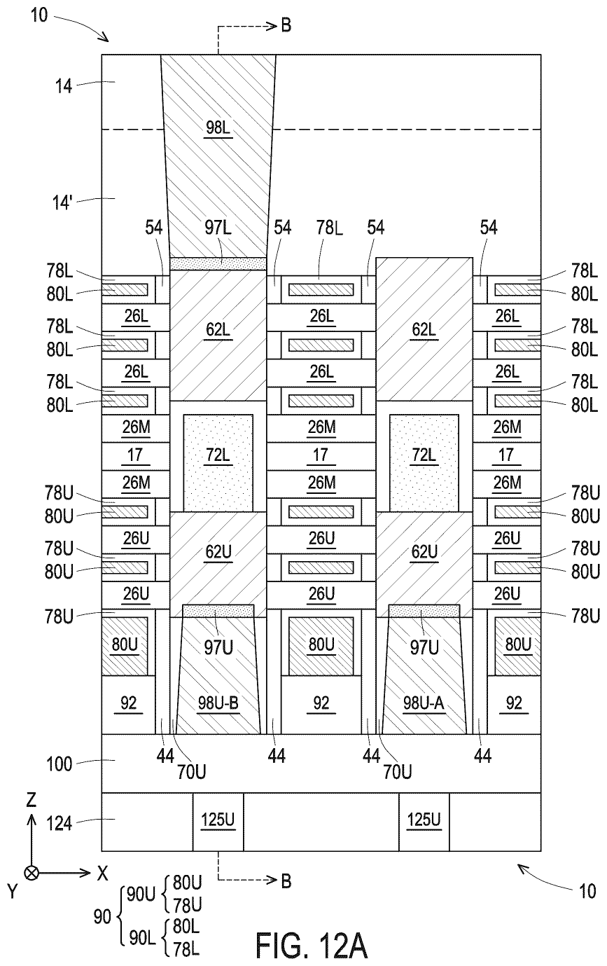

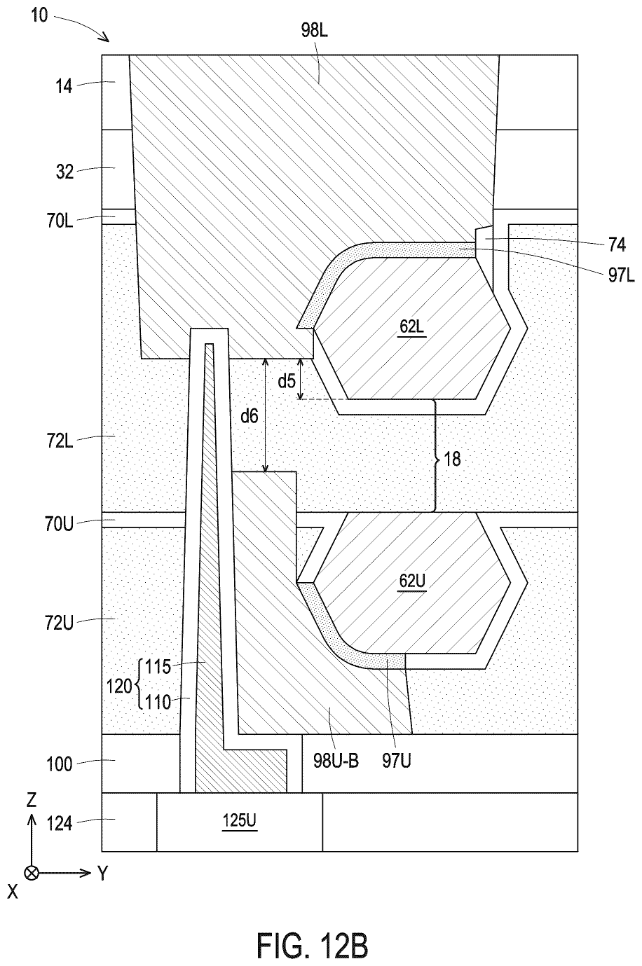

Referring to FIG. 2, FIG. 12A, and FIG. 12B, method 200 at block 230 includes forming a lower source/drain contact in the lower source/drain contact opening. For example, a lower source/drain contact 98L is formed in lower source/drain contact opening 128. Source/drain contact 98L is formed over silicide layer 97L. In FIG. 12B, source/drain contact 98L extends through substrate 14, isolation features 32, CESL 70L, and into ILD layer 72L. In such embodiments, a thickness of source/drain contact 98L (e.g., along the z-direction) is greater than a sum of a thickness of substrate 14, isolation features 32, and CESL 70L. Source/drain contact 98L is disposed on a bottom and a sidewall of epitaxial source/drain 62L (e.g., on at least two facets thereof), and source/drain contact 98L is disposed on a bottom and sidewalls of source/drain via 120. In the depicted embodiment, source/drain contact 98L extends beyond the bottom of source/drain via 120 and wraps bottom portion 132 thereof. Further, distance d5 is between a bottom of source/drain contact 98L and the top of epitaxial source/drain, and distance d6 is between the bottom of source/drain contact 98L the bottom of source/drain contact 98U-B. In some embodiments, source/drain contact 98L does not extend beyond the bottom of source/drain via 120. In some embodiments, source/drain contact 98L extends below the top of epitaxial source/drain 62L but not to source/drain contact 98U-B. In some embodiments, source/drain contact 98L has a generally L-shaped profile with a horizontal portion/extension (e.g., along the y-direction) and a vertical portion/extension (e.g., along the z-direction).

Source/drain contact 98L includes an electrically conductive material, such as tungsten, ruthenium, cobalt, molybdenum, copper, aluminum, titanium, tantalum, iridium, palladium, platinum, nickel, tin, gold, silver, other suitable metal, alloys thereof, or a combination thereof. In the depicted embodiment, similar to source/drain contacts 98U, source/drain contact 98L is a barrier-free metal plug, such as a tungsten plug, a cobalt plug, or a ruthenium plug. For example, source/drain contact 98L includes a metal bulk layer, such as a tungsten plug, that physically, directly contacts surrounding dielectric materials, such as ILD layer 72L, CESL 70L, isolation features 32, or a combination thereof. In some embodiments, source/drain contact 98L includes a metal bulk layer and a metal liner, where the metal liner is between the metal bulk layer and surrounding dielectric materials. In some embodiments, the metal liner is between the metal bulk layer and silicide layer 97L.

In some embodiments, forming lower source/drain contact 98L includes depositing at least one electrically conductive material (e.g., a metal bulk material) over the backside of stacked device structure 10 (e.g., substrate 14 thereof) that fills source/drain contact opening 128 and performing a planarization process (e.g., CMP) to remove portions of the at least one electrically conductive material that are disposed over the backside of stacked device structure 10. The planarization process may be performed until reaching and exposing substrate 14, isolation features 32, CESL 70L, or a combination thereof. Remainders of the electrically conductive material form metal plugs and, in some embodiments, metal liners. In some embodiments, substrate 14 functions as a planarization stop layer. In some embodiments, one or more insulation layers may be deposited in source/drain contact opening 128 and processed to form contact spacers, such as dielectric layers and/or air gaps, along sidewalls of the electrically conductive portions of source/drain contact 98L. In some embodiments, a blanket deposition process (e.g., blanket CVD), such as described above, forms a metal bulk material (e.g., tungsten) of source/drain contact 98L. In some embodiments, a bottom-up deposition process (e.g., selective CVD), such as described above, fills source/drain contact opening 128 with a metal bulk material (e.g., tungsten) of source/drain contact 98L.

In some embodiments, after forming source/drain contact 98L, a thinning process and/or a de-bonding process may be performed to remove the carrier wafer from the frontside of stacked device structure 10. For example, a planarization process, such as CMP, or an etching process can be performed to remove the carrier wafer. In some embodiments, after forming source/drain contact 98L, substrate 14 may be removed from stacked device structure 10 by CMP and/or other suitable planarization process, thereby exposing isolation features 32, CESL 70L, or ILD layer 72L. The planarization process may stop upon reaching isolation features 32, CESL 70L, or ILD layer 72L. In some embodiments, substrate 14 is removed by an etching process. In some embodiments, substrate 14 may be replaced with an insulator layer. For example, after removing substrate 14, processing may include depositing at least one dielectric layers over a backside of stacked device structure 10, such as over isolation features 32, CESL 70L, ILD layer 72L, source/drain contact 98L, or a combination thereof, and performing a planarization process on the at least one dielectric layer. The planarization process may stop upon reaching source/drain contact 98L. In some embodiments, a combination of etching and polishing is implemented to remove substrate 14 from stacked device structure 10.

Referring to FIG. 13A, FIG. 13B, and FIG. 14, processing may include flipping over stacked device structure 10. As described herein, stacked device structure 10 includes transistor 20U and transistor 20L, which are fabricated as GAA transistors (i.e., a transistor having a gate that surrounds at least one suspended channel (for example, nanowires, nanosheets, nanobars, etc.), where the at least one suspended channel extends between source/drains). The GAA transistors may be p-type GAA transistors or n-type GAA transistors. In the depicted embodiment, transistor 20U is an n-type GAA transistor that includes a channel (e.g., semiconductor layers 26U), source/drains (e.g., epitaxial source/drains 62U), and a gate (e.g., gate stack 90U), and transistor 20L is a p-type GAA transistor that includes a channel (e.g., semiconductor layers 26L), source/drains (e.g., epitaxial source/drains 62L), and a gate (e.g., gate stack 90L). The gates engage the respective channels extending between the respective source/drains, and current can flow between source/drains (e.g., between source and drain or vice versa) during operation. In the depicted embodiment, the gates are on a top and a bottom of the channels in the X-Z plane, and the gates surround the channels in the Y-Z plane (e.g., gate stack 90U is disposed on a top, a bottom, and sidewalls of semiconductor layers 26U and gate stack 90L is disposed on a top, a bottom, and sidewalls of semiconductor layers 26L). In some embodiments, transistor 20U and/or transistor 20L are fabricated as a fork sheet transistor. In such embodiments, the gate partially surrounds and/or wraps the channel.

Stacked device structure 10 further includes a device-level interconnect (also referred to as an MOL interconnect) that includes an upper source/drain contact (e.g., source/drain contact 98U-B), a lower source/drain contact (e.g., source/drain contact 98L), and a source/drain via (e.g., source/drain via 120) that connects the upper source/drain contact and the lower source/drain contact. To enhance thermal stability during subsequent processing and minimize resistivity, the disclosed device-level interconnect includes a ruthenium-and-aluminum comprising source/drain via. For example, in FIG. 13A, FIG. 13B, FIG. 14, and as described above, source/drain via 120 includes an aluminum-comprising via liner (e.g., via liner 110) and a ruthenium-comprising via plug (e.g., via plug 115), such as an aluminum liner (e.g., formed by PVD) and a ruthenium plug (e.g., formed by CVD), respectively. Because the ruthenium-comprising plug can withstand higher temperature processing, such as that associated with MOL and/or BEOL processing, than copper plugs, source/drain via 120 exhibits better thermal stability than source/drain vias having copper plugs. In some embodiments, the ruthenium-comprising plug (e.g., via plug 115) has an atomic concentration of ruthenium that is greater than about 45 atomic percent (at %) to ensure thermal stability at high temperatures. Further, since the ruthenium-comprising plug adheres well to the aluminum-comprising via liner compared to dielectric materials (e.g., dielectric layer 100, ILD layer 72U, CESL 70U, ILD layer 72L, or a combination thereof), the aluminum-comprising via liner reduces ruthenium agglomeration that may cause voids in the device-level interconnect (e.g., within and/or between a ruthenium plug and adjacent dielectric materials) that increase resistance and/or decrease reliability thereof. In some embodiments, thickness T1 of the aluminum-comprising liner (e.g., via liner 110) is about 1 nm to about 2 nm. Aluminum-comprising liners that are too thin (e.g., having thicknesses less than 1 nm) may not adequately cover surfaces forming source/drain via opening 102 (and thus result in discontinuous sidewall coverage and inadequate reduction of ruthenium agglomeration), while aluminum-comprising liners that are too thick (e.g., having thicknesses greater than 2 nm) may introduce significant sidewall scattering that can negatively impact an intermix of ruthenium and aluminum and/or resistance of the ruthenium-comprising plug. Even further, incorporating aluminum into source/drain via 120 lowers its resistivity compared to source/drain vias including only ruthenium, which can improve electrical current flow and thus performance of stacked device structure 10 (e.g., transistors thereof). Different embodiments may have different advantages, and no particular advantage is required of any embodiment.

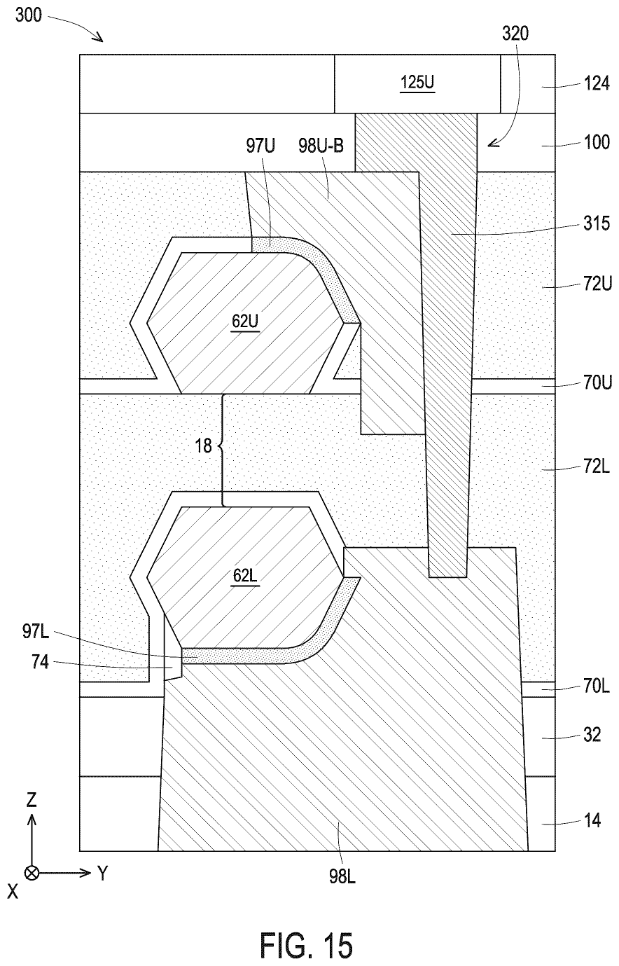

In some embodiments, to enhance thermal stability and minimize resistivity, the disclosed device-level interconnect may include a barrier-free ruthenium-and-aluminum comprising source/drain via. FIG. 15 is a cross-sectional view of a stacked device structure 300 having a ruthenium-and-aluminum comprising source/drain via, in portion or entirety, according to various aspects of the present disclosure. For clarity and simplicity, similar features of stacked device structure 10 and stacked device structure 300 are identified by the same reference numerals. In FIG. 15, stacked device structure 300 has a device-level interconnect that includes a source/drain via 320 that is physically and/or electrically connected to source/drain contact 98U-B and source/drain contact 98L. Source/drain via 320 electrically connects epitaxial source/drain 62U (which is physically and/or electrically connected to source/drain contact 98U-B) and epitaxial source/drain 62L (which is physically and/or electrically connected to source/drain contact 98L). In FIG. 15, source/drain via 320 includes a ruthenium-and-aluminum comprising plug 315, such as a ruthenium aluminide plug, that physically contacts source/drain contact 98U-B, source/drain contact 98L, and dielectric layers (e.g., dielectric layer 100, ILD layer 72U, CESL 70U, and ILD layer 72L). In some embodiments, ruthenium-and-aluminum comprising plug 315 is a binary ruthenium alloy plug. In some embodiments, ruthenium-and-aluminum comprising plug 315 exhibits improved adhesion (e.g., compared to barrier-free ruthenium plugs), low resistivity (e.g., about 13 μΩ-cm to about 15 μΩ-cm), thermal stability at high temperatures (e.g., compared to copper-comprising source/drain vias), or a combination thereof. In some embodiments, ruthenium-and-aluminum comprising plug 315 has an atomic concentration of ruthenium that is greater than about 45 at % to ensure thermal stability at high temperatures. Different embodiments may have different advantages, and no particular advantage is required of any embodiment. FIG. 15 has been simplified for the sake of clarity to better understand the inventive concepts of the present disclosure. Additional features can be added in stacked device structure 300, and some of the features described below can be replaced, modified, or eliminated in other embodiments of stacked device structure 300.

Returning to FIG. 13A, FIG. 13B, and FIG. 14, in the depicted embodiment, source/drain via 120 electrically connects epitaxial source/drains on a same side of gate 90, such as epitaxial source/drain 62U disposed directly above epitaxial source/drain 62L (i.e., an upper epitaxial source/drain and a lower epitaxial source/drain of a same epitaxial source/drain stack). In some embodiments, epitaxial source/drain 62U is a drain of transistor 20U, epitaxial source/drain 62L is a drain of transistor 20L, and source/drain via 120 electrically connects the drains of transistor 20U and transistor 20L. In some embodiments, epitaxial source/drain 62U is a source of transistor 20U, epitaxial source/drain 62L is a source of transistor 20L, and source/drain via 120 electrically connects the sources of transistor 20U and transistor 20L.

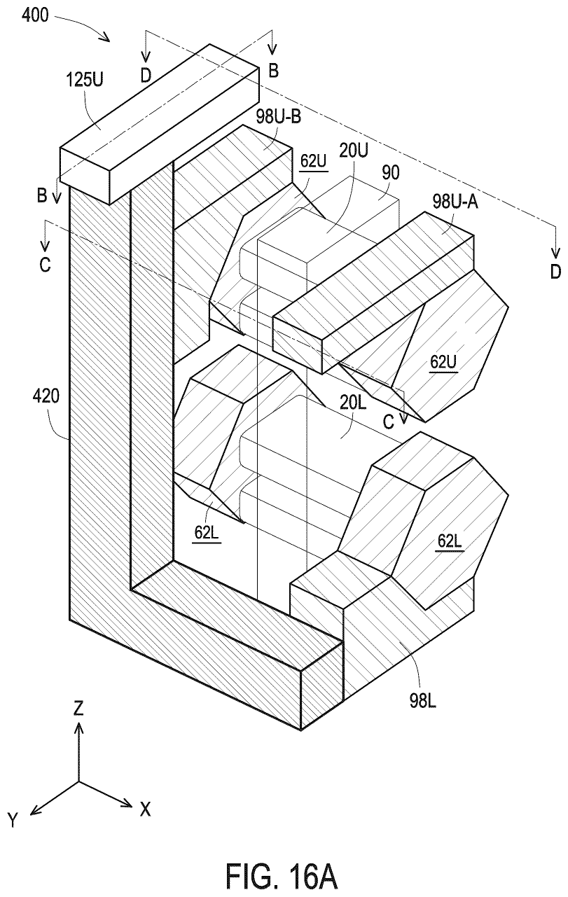

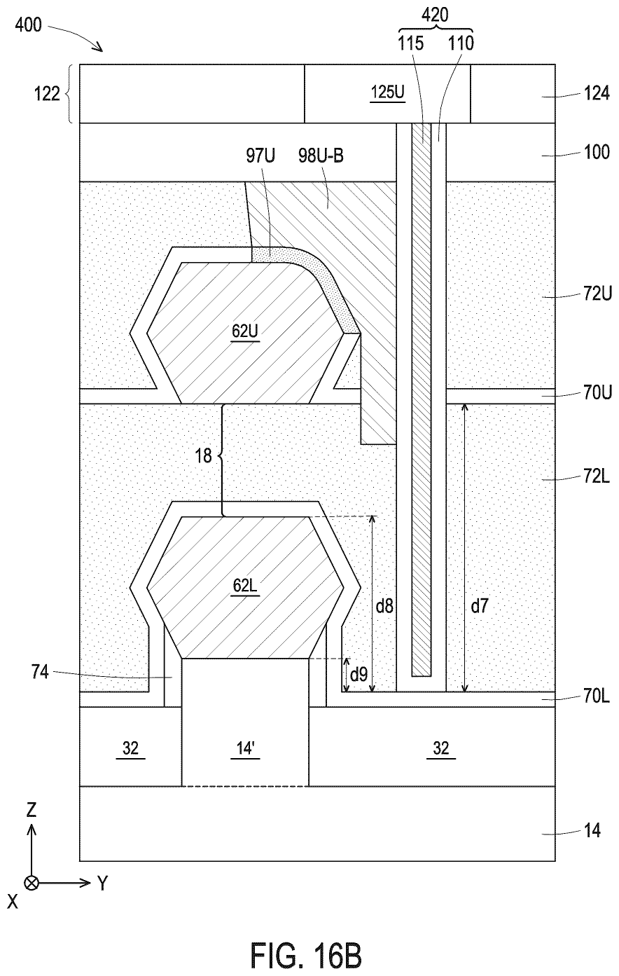

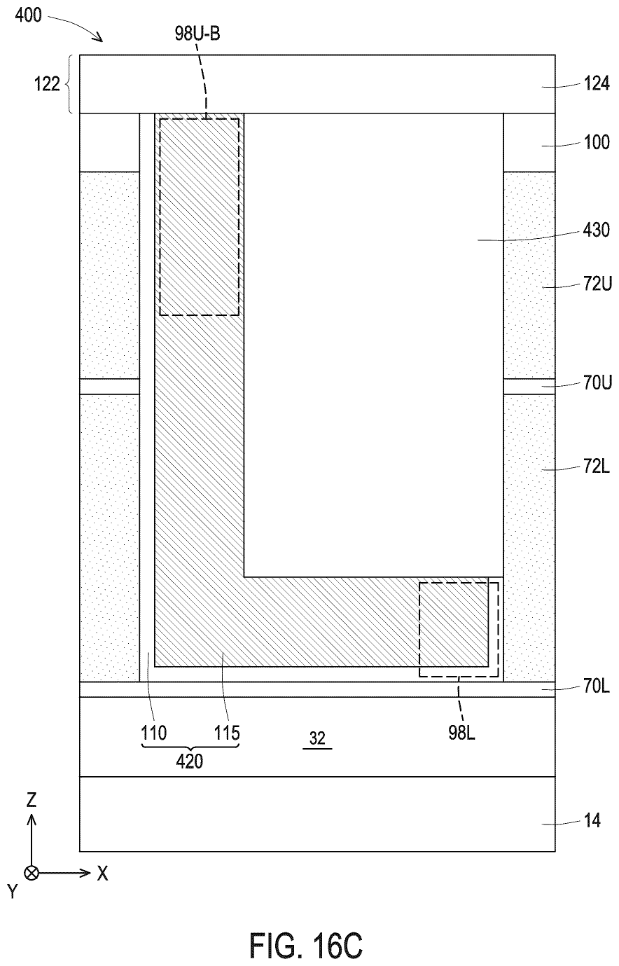

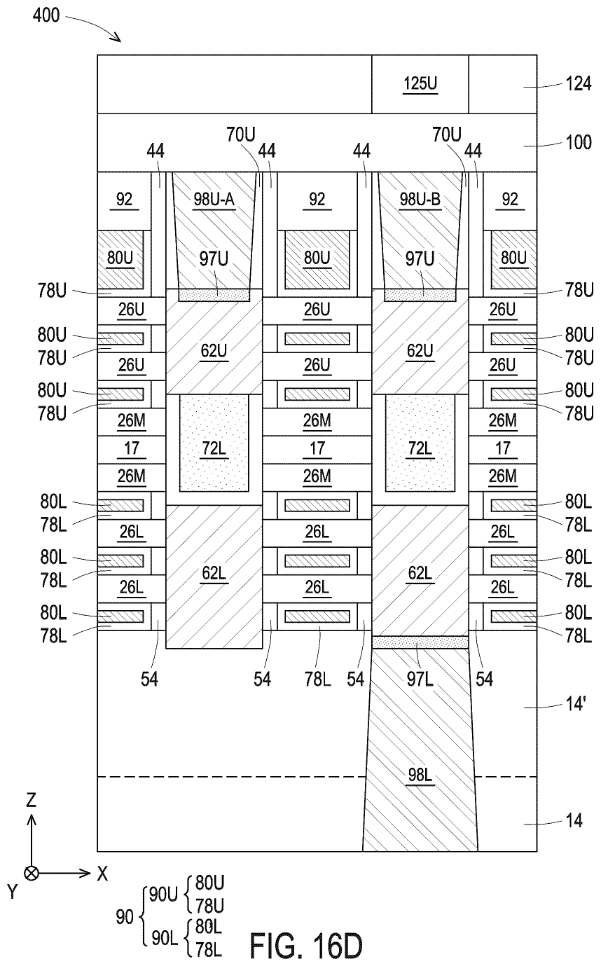

Turning to FIGS. 16A-16D, in some embodiments, the disclosed source/drain via may electrically connect epitaxial source/drains on opposite sides of gate 90. FIG. 16A is a perspective view of a stacked device structure 400, in portion or entirety, according to various aspects of the present disclosure. FIG. 16B is a cross-sectional view of stacked device structure 400, in portion or entirety, along line B-B of FIG. 16A, according to various aspects of the present disclosure. FIG. 16C is a cross-sectional view of stacked device structure 400, in portion or entirety, along line C-C of FIG. 16A, according to various aspects of the present disclosure. FIG. 16D is a cross-sectional view of stacked device structure 400, in portion or entirety, along line D-D of FIG. 16A, according to various aspects of the present disclosure. For clarity and simplicity, similar features of stacked device structure 10 and stacked device structure 400 are identified by the same reference numerals. FIGS. 16A-16D have been simplified for the sake of clarity to better understand the inventive concepts of the present disclosure. Additional features can be added in stacked device structure 400, and some of the features described below can be replaced, modified, or eliminated in other embodiments of stacked device structure 400.

In FIGS. 16A-16D, stacked device structure 400 has a source/drain via 420 that electrically connects epitaxial source/drains on opposite sides of gate 90, such as epitaxial source/drain 62U of a first epitaxial source/drain stack on a first side of gate 90 and epitaxial source/drain 62L of a second epitaxial source/drain on a second, opposite side of gate 90. To enhance thermal stability and minimize resistivity as described herein, source/drain via 420 is a ruthenium-and-aluminum comprising source/drain via, and in the depicted embodiment, source/drain via 420 includes via liner 110 and via plug 115.

Source/drain via 420 extends below bottoms of epitaxial source/drains 62U, below tops of epitaxial source/drains 62L, and below bottoms of epitaxial source/drains 62L. For example, in FIG. 16B, source/drain via 420 extends a distance d7 below the bottoms of epitaxial source/drains 62U (and below a top of insulation structure 18), a distance d8 below the tops of epitaxial source/drains 62L, and a distance d9 below the bottoms of epitaxial source/drains 62L. In the depicted embodiment, source/drain via 420 extends to CESL 70L. In some embodiments, source/drain via 420 extends below the tops of epitaxial source/drains 62L but not the bottoms thereof. In some embodiments, source/drain via 420 extends below the bottom of source/drain contact 98U-B but not below the tops of epitaxial source/drains 62L.

In FIG. 16C, source/drain via 420 has a generally L-shaped profile with a horizontal portion/extension (e.g., along the x-direction) and a vertical portion/extension (e.g., along the z-direction). The vertical portion of source/drain via 420 overlaps and is physically and/or electrically connected to source/drain contact 98U-B (which is physically and/or electrically connected to epitaxial source/drain 62U of the first epitaxial source/drain stack on the first side of gate 90). The horizontal portion of source/drain via 420 overlaps and is physically and/or electrically connected to source/drain contact 98L (which is physically and electrically connected to epitaxial source/drain 62L of the second epitaxial source/drain stack on the second side of gate 90). The vertical portion may be referred to as a via (VD) of source/drain via 420, the horizontal portion may be referred to as a line interconnect (LI), and source/drain via 420 may be referred to as a via-line interconnect (VD-LI) of the device-level interconnect of stacked device structure 400. An insulation structure 430 fills space between source/drain via 420 and dielectric layers (e.g., dielectric layer 100, ILD layer 72U, CESL 70U, and ILD layer 72L). Configuring source/drain via 420 with an L-shaped profile reduces overlap between source/drain via 420 and gate 90, which reduces a size of any parasitic capacitor that may form therebetween (such as that formed by source/drain via 420, gate 90, and a dielectric material therebetween (e.g., along the y-direction)), and thus reduces gate-to-contact parasitic capacitance that can degrade reliability and/or performance of stacked device structure 10. Different embodiments may have different advantages, and no particular advantage is required of any embodiment.

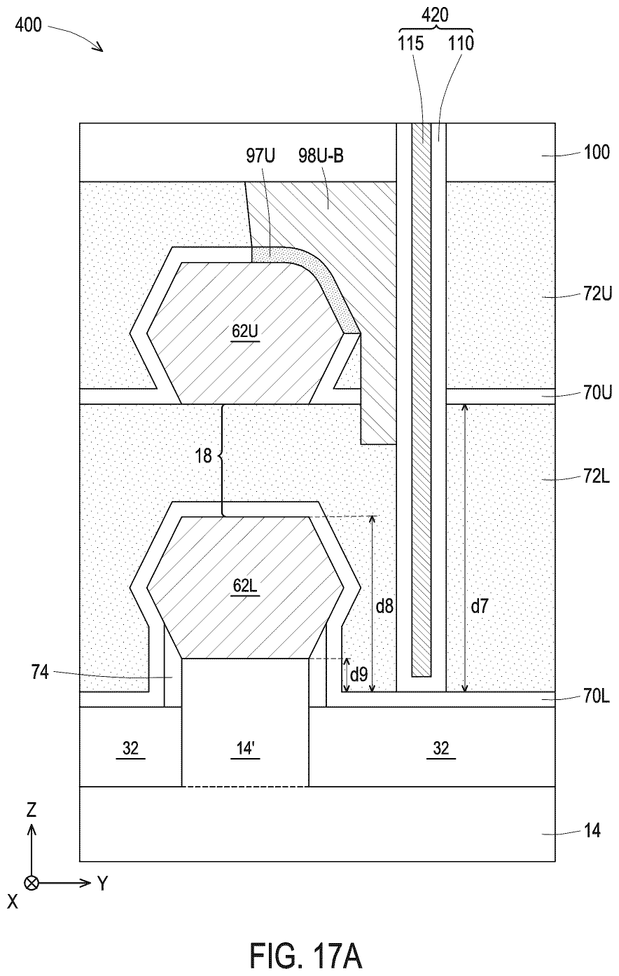

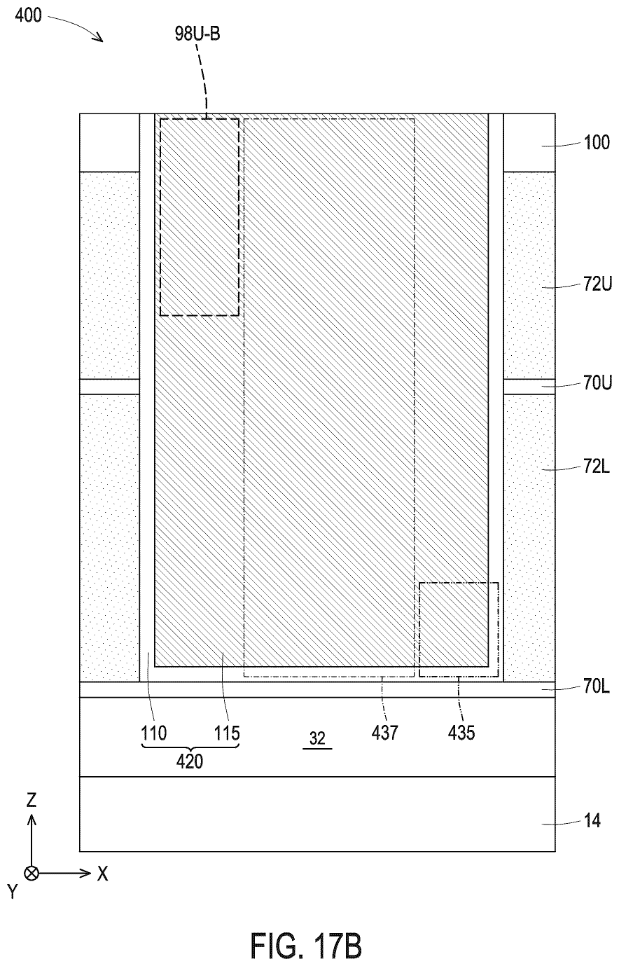

FIGS. 17A-20A and FIGS. 17B-20B are cross-sectional views of a stacked device structure 400, in portion or entirety, at fabrication stages directed to configuring a profile of source/drain via 420 according to various aspects of the present disclosure. The cross-sectional views of FIGS. 17A-20A and FIGS. 17B-20B are cut along a gate lengthwise direction (e.g., a y-direction) and a gate widthwise direction (e.g., an x-direction), respectively. FIGS. 17A-20A and FIGS. 17B-20B have been simplified for the sake of clarity to better understand the inventive concepts of the present disclosure. Additional steps can be provided before, during, and after the method depicted in FIGS. 17A-20A and FIGS. 17B-20B, and some of the steps described can be moved, replaced, or eliminated for additional embodiments of the method depicted in FIGS. 17A-20A and FIGS. 17B-20B. Additional features can be added in stacked device structure 400, and some of the features described below can be replaced, modified, or eliminated in other embodiments of stacked device structure 400.

Referring to FIG. 17A and FIG. 17B, stacked device structure 400 is depicted after forming source/drain via 420 in a manner similar to that described above with reference to FIGS. 3A-8A and FIGS. 3B-8B. In FIG. 17B, source/drain via 420 has a generally rectangular profile, and source/drain via 420 overlaps source/drain contact 98U-B, a lower source/drain contact area 435 (i.e., an area where source/drain contact 98L to epitaxial source/drain 62L of the second epitaxial source/drain stack is formed during backside processing), and a gate area 437 (i.e., where source/drain via 420 may overlap gate 90 and a dielectric material is disposed between source/drain via 420 and gate 90 along the y-direction). Source/drain via 420 is physically and/or electrically connected to source/drain contact 98U-B. In some embodiments, such as depicted, source/drain via 420 also overlaps an area where a lower source/drain contact may be formed to epitaxial source/drain 62L of the first epitaxial source/drain stack during backside processing, but any lower source/drain contact formed thereto will not be physically and/or electrically connected to source/drain via 420. In some embodiments, such lower source/drain contact may be physically and/or electrically connected to source/drain via 420 depending on a design of stacked device structure 400 and its device-level interconnect.

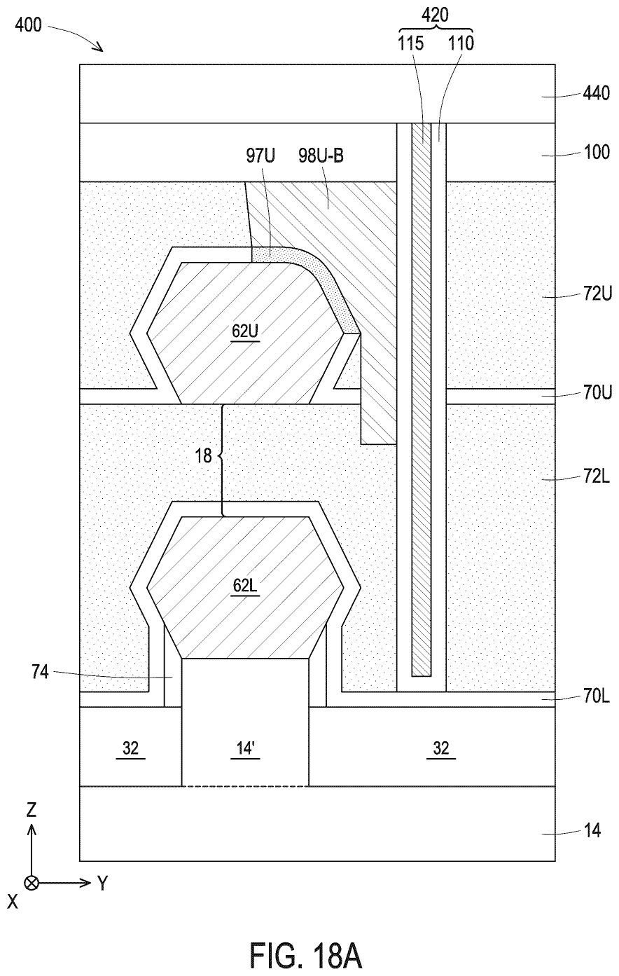

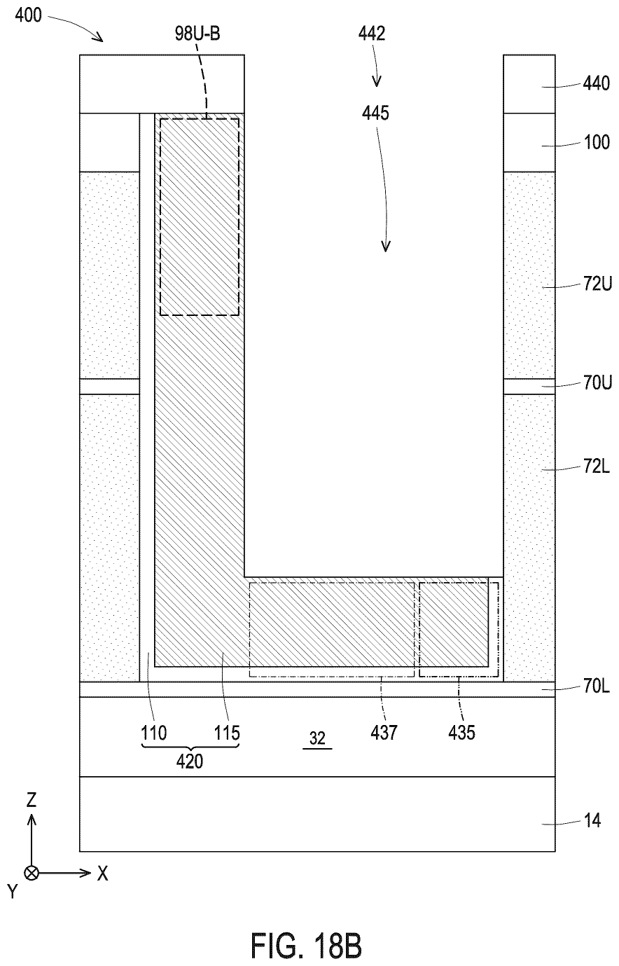

Referring to FIG. 18A and FIG. 18B, to reduce gate-to-contact parasitic capacitance, such as that between gate 90 and source/drain via 420, a source/drain via etch (e.g., a metal etch) may be performed to reduce overlap of source/drain via 420 and gate 90 and/or to configure a profile of source/drain via 420. In some embodiments, a patterning process removes a portion of source/drain via 420 to reduce area 437 of overlap between source/drain via 420 and gate 90, while maintaining overlap of source/drain via 420 and area 435, overlap of source/drain via 420 and source/drain contact 98U-B, and connection between a portion of source/drain via 420 that overlaps area 435 and a portion of source/drain via 420 that overlaps source/drain contact 98U-B. In the depicted embodiment, the patterning process provides source/drain via 420 with a generally L-shaped profile that significantly reduces area 437 while maintaining connection of source/drain via 420 to source/drain contact 98U-B and area 435.

Source/drain via 420 may be patterned by a lithography process and an etching process. The lithography process may include forming a patterned mask layer 440 over source/drain via 420 and dielectric layer 100. Patterned mask layer 440 has an opening 442 therein that exposes a portion of source/drain via 420. The etching process uses patterned mask layer 440 as an etch mask, and the etching process is configured to selectively remove the exposed portion of source/drain via 420 with negligible removal of dielectric layer 100, ILD layer 72U, CESL 70U, and ILD layer 72L. For example, an etchant is selected for the etch process that removes metal-comprising materials (i.e., via plug 115 and via liner 110) at a higher rate than dielectric material (i.e., dielectric layer 100, ILD layer 72U, CESL 70U, ILD layer 72L, or a combination thereof) (i.e., the etchant has a high etch selectivity with respect to metal materials). The etching process is a dry etch, a wet etch, other suitable etching process, or a combination thereof. In some embodiments, the etching process is a reactive ion etch (RIE), such as a ruthenium RIE. In some embodiments, the etching process removes patterned mask layer 440, in portion or entirety. In some embodiments, after the etching process, patterned mask layer 440 is removed, for example, by an etching process and/or a resist stripping process.

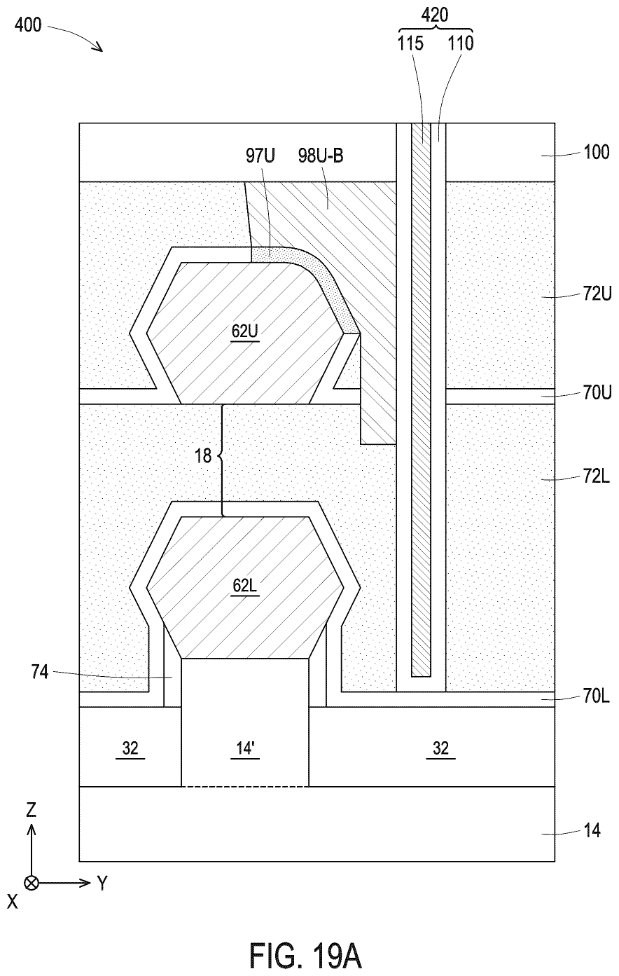

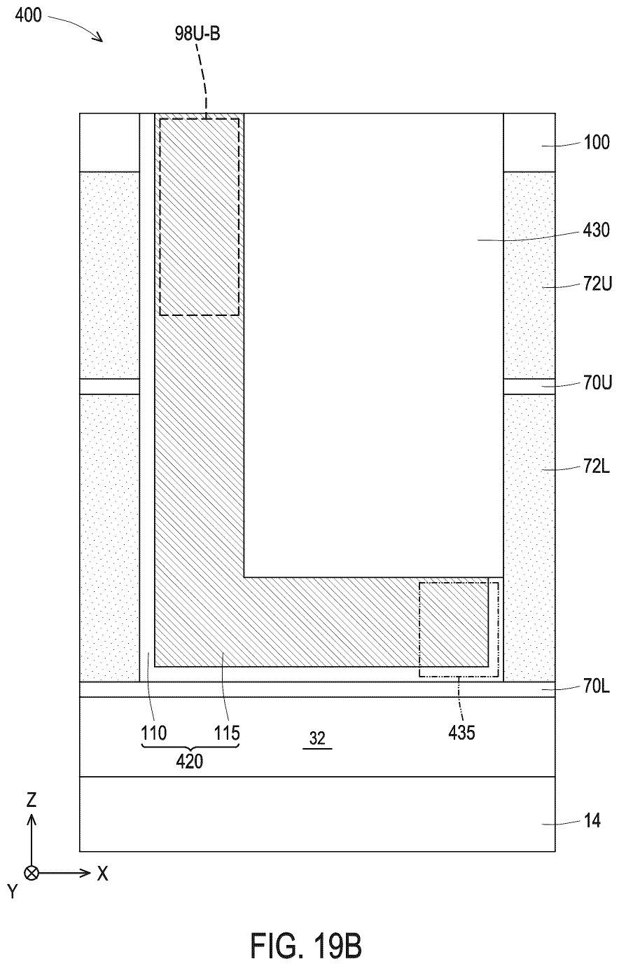

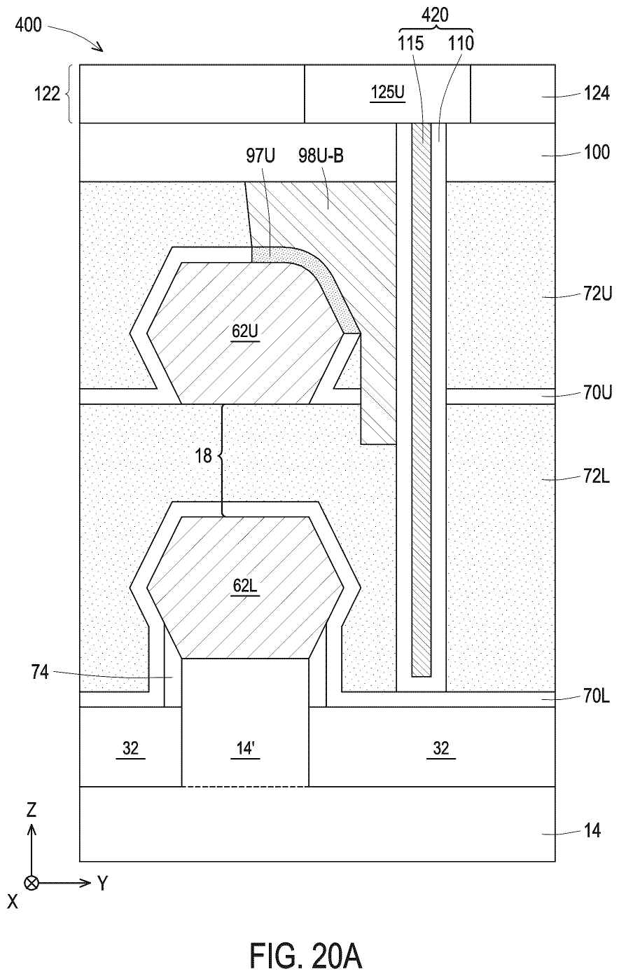

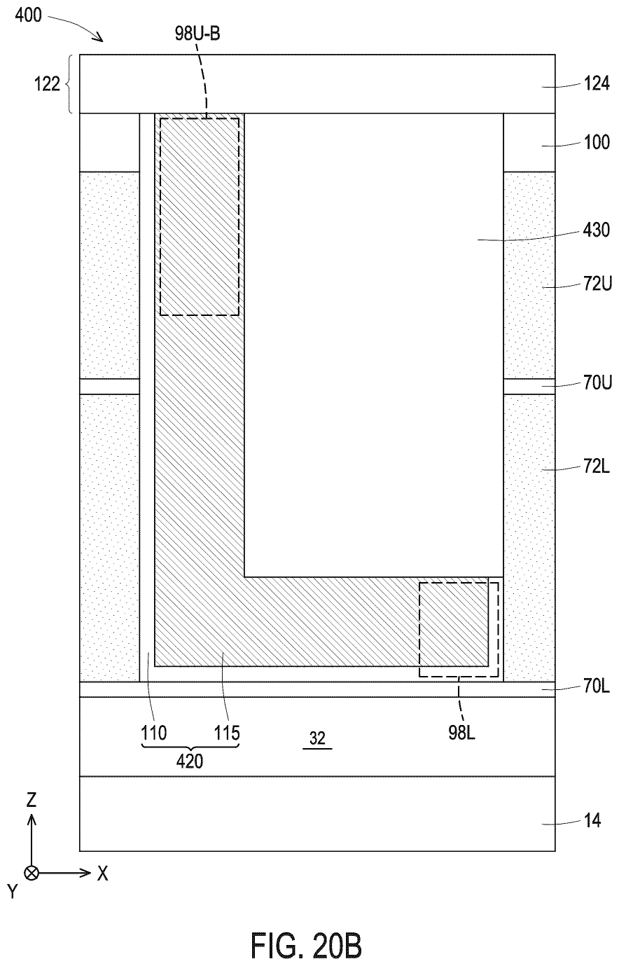

Stacked device structure 400 has an opening 445 therein after the etching process. Opening 445 has a sidewall formed by via plug 115, a bottom formed by via plug 115 and via liner 110, and a sidewall formed by dielectric layers (e.g., dielectric layer 100, ILD layer 72U, CESL 70U, and ILD layer 72L). Referring to FIG. 19A and FIG. 19B, processing may include forming insulation structure 430 in opening 445. Insulation structure 430 includes a dielectric material, which may include silicon, oxygen, carbon, nitrogen, other suitable dielectric constituent, or a combination thereof (e.g., silicon oxide, silicon nitride, silicon oxynitride, silicon carbide, silicon carbonitride, silicon oxycarbide, silicon oxycarbonitride, or a combination thereof). Insulation structure 430 may be a single layer structure or a multilayer structure. In some embodiments, insulation structure 430 is formed by depositing at least one dielectric material/layer over dielectric layer 100 that fills opening 445 and performing a planarization process. The planarization process may stop upon reaching source/drain via 420. Referring to FIG. 20A and FIG. 20B, processing may then proceed on stacked device structure 400 in a manner similar to that described above with reference to FIGS. 9A-13A and FIGS. 9B-13B. For example, backside processing may be performed to form source/drain contact 98L on epitaxial source/drain 62L (of the second epitaxial source/drain stack), and source/drain contact 98L is physically and/or electrically connected to source/drain via 420.

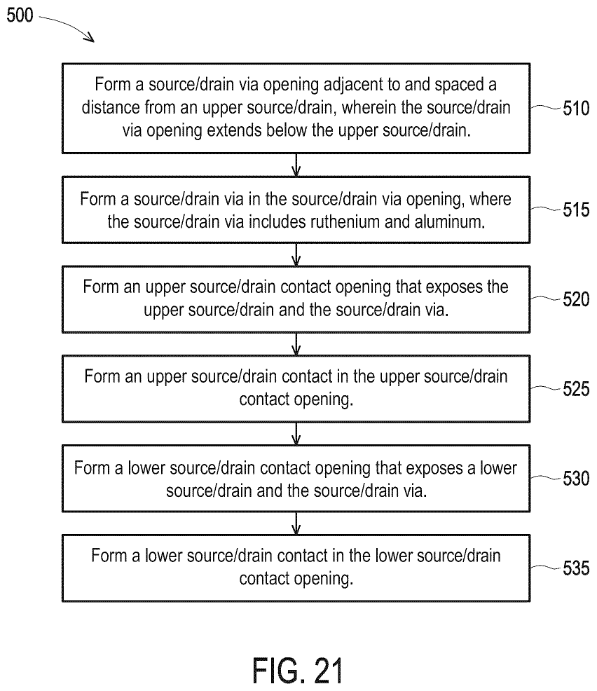

FIG. 21 is a flow chart of a method 500, in portion or entirety, for fabricating a device-level interconnect structure for a stacked device structure, such as the stacked device structures described herein, according to various aspects of the present disclosure. In method 500, a source/drain via (e.g., source/drain via 120, source/drain via 320, source/drain via 420, etc.) is formed before source/drain contacts. For example, method 500 at block 510 includes forming a source/drain via opening adjacent to and spaced a lateral distance from an upper source/drain. The source/drain via opening extends vertically below the upper source/drain, such as beyond a bottom surface of the upper source/drain. The source/drain via opening may span a distance between the upper source/drain and a lower source/drain. In some embodiments, the source/drain via opening extends below a top of the lower source/drain. In some embodiments, the source/drain via opening extends below a bottom of the lower source/drain. In some embodiments, the source/drain via opening is formed in a gate cut isolation structure (e.g., a dielectric structure that isolates gate 90 from a gate of a different device and which may have been formed by removing a portion of a common gate structure therebetween and replacing the portion of the common gate structure with one or more electrically insulating layers). In such embodiments, the source/drain via may be formed in a manner similar to that described above with reference to FIGS. 17A-20A and FIGS. 17B-20B, except the source/drain via is formed in the gate cut isolation structure, which may be disposed and/or embedded in ILD layer 72U, CESL 70U, ILD layer 72L, CESL 70L, or a combination thereof. Method 500 at block 515 includes forming a source/drain via in the source/drain via opening. The source/drain via includes ruthenium and aluminum, such as described herein. Method 500 may then include forming an upper source/drain contact opening that exposes the upper source/drain and the source/drain via at block 520, forming an upper source/drain contact in the upper source/drain contact opening at block 525, forming a lower source/drain contact opening that exposes the lower source/drain and the source/drain via at block 530, and forming a lower source/drain contact in the lower source/drain contact opening at block 535. The upper source/drain contact may be formed before or after the lower source/drain contact. FIG. 21 has been simplified for the sake of clarity to better understand the inventive concepts of the present disclosure. Additional steps can be provided before, during, and after method 500, and some of the steps described can be moved, replaced, or eliminated for additional embodiments of method 500.

In some embodiments, transistor 20U and/or transistor 20L are fabricated as a FinFET. In such embodiments, the gate partially surrounds and/or wraps the channel. For example, the channel is a portion of a semiconductor fin extending from substrate 14, the gate stack is on a top of the semiconductor fin in the X-Z plane, and the gate stack wraps the semiconductor fin in the Y-Z plane (i.e., the gate stack is disposed on a top and sidewalls of the semiconductor fin). In such embodiments, a gate dielectric and a gate electrode of the gate are formed over a top and sidewalls of a semiconductor fin.

In some embodiments, transistor 20U and/or transistor 20L are fabricated as a planar transistor. In such embodiments, the gate stack is disposed on one side of the channel (e.g., a top surface). For example, the channel is a portion of a semiconductor substrate, and the gate stack is disposed on a top surface of semiconductor substrate in the X-Z plane and the Y-Z plane. In such embodiments, a gate dielectric and a gate electrode of the gate are formed over a top of a channel region of a semiconductor substrate.

Devices and/or structures described herein, such as stacked device structure 10, device 12U, device 12L, transistor 20L, transistor 20U, etc. may be included in a microprocessor, a memory, other IC device, or a combination thereof. In some embodiments, devices and/or structures described herein, such as stacked device structure 10, device 12U, device 12L, transistor 20L, transistor 20U, etc. described herein are a portion of an IC chip, a system on chip (SoC), or portion thereof, that includes various passive and active microelectronic devices, such as resistors, capacitors, inductors, diodes, p-type FETs (PFETs), n-type FETs (NFETs), metal-oxide semiconductor FETs (MOSFETs), complementary metal-oxide semiconductor (CMOS) transistors, bipolar junction transistors (BJTs), laterally diffused MOS (LDMOS) transistors, high voltage transistors, high frequency transistors, other devices, or a combination thereof.

The present disclosure provides for many different embodiments. Thermally stable device-level interconnects for stacked device structures, such as stacked transistor structures, and methods of fabrication thereof, are disclosed herein and provide numerous advantages as described herein. The device-level interconnects disclosed herein are particularly well suited for withstanding high temperature processes performed during BEOL processing.

An exemplary method includes forming an upper source/drain contact to an upper epitaxial source/drain and forming a source/drain via opening that exposes the upper source/drain contact. The source/drain via opening extends below the upper epitaxial source/drain. The method further includes forming a source/drain via that includes ruthenium and aluminum in the source/drain via opening. The source/drain via is disposed on the upper source/drain contact. The method further includes forming a lower source/drain contact opening that exposes a lower epitaxial source/drain and the source/drain via and forming a lower source/drain contact in the lower source/drain contact opening. The source/drain via spans between and connects the upper source/drain contact and the lower source/drain contact. In some embodiments, the lower source/drain contact opening exposes a bottom and sidewalls of the source/drain via and the lower source/drain contact wraps a lower end of the source/drain via.

In some embodiments, the upper epitaxial source/drain and the lower epitaxial source/drain form an epitaxial source/drain stack, and the upper epitaxial source/drain and the lower epitaxial source/drain are on a same side of a gate. In some embodiments, the upper epitaxial source/drain is a portion of a first epitaxial source/drain stack, the lower epitaxial source/drain is a portion of a second epitaxial source/drain stack, and a gate is disposed between the first epitaxial source/drain stack and the second epitaxial source/drain stack.

In some embodiments, the source/drain via opening exposes a top and a sidewall of the upper source/drain contact and the source/drain via opening extends below a bottom of the upper epitaxial source/drain. In some embodiments, forming the source/drain via includes filling the source/drain via opening with an electrically conductive material that includes ruthenium, aluminum, or a combination thereof and performing a planarization process.

In some embodiments, filling the source/drain via opening with the electrically conductive material includes forming an aluminum layer that partially fills the source/drain via opening and forming a ruthenium layer over the aluminum layer. The ruthenium layer fills a remainder of the source/drain via opening, and the aluminum layer wraps the ruthenium layer. In some embodiments, forming the aluminum layer includes performing a physical vapor deposition process. In some embodiments, the forming the ruthenium layer includes performing a chemical vapor deposition process.

In some embodiments, filling the source/drain via opening with the electrically conductive material includes forming a ruthenium aluminide plug. In some embodiments, filling the source/drain via opening with the electrically conductive material includes forming a ruthenium aluminide layer that partially fills the source/drain via opening and forming a ruthenium layer over the ruthenium aluminide layer. The ruthenium layer fills a remainder of the source/drain via opening, and the ruthenium aluminide layer wraps the ruthenium layer.

An exemplary semiconductor structure includes an upper source/drain contact disposed on an upper epitaxial source/drain, a lower source/drain contact disposed on a lower epitaxial source/drain, and a source/drain via connected to the upper source/drain contact and the lower source/drain contact. The source/drain via is disposed on the upper source/drain contact, the source/drain via extends below the upper source/drain contact, and the source/drain via includes ruthenium and aluminum. In some embodiments, the source/drain via includes a ruthenium plug wrapped by an aluminum liner. In some embodiments, the source/drain via includes a ruthenium aluminide plug. In some embodiments, the source/drain via includes a ruthenium plug wrapped by a ruthenium aluminide liner. In some embodiments, the source/drain via extends below a top of the lower epitaxial source/drain.

The semiconductor structure may further include a gate. In some embodiments, the upper epitaxial source/drain and the lower epitaxial source/drain form an epitaxial source/drain stack disposed adjacent to the gate, and the upper epitaxial source/drain and the lower epitaxial source/drain are on a same side of the gate. In some embodiments, the upper epitaxial source/drain is a portion of a first epitaxial source/drain stack, the lower epitaxial source/drain is a portion of a second epitaxial source/drain stack, and the gate is disposed between the first epitaxial source/drain stack and the second epitaxial source/drain stack.

An exemplary device includes a transistor stack having a first transistor over a second transistor. The first transistor includes a first channel layer, a first gate, and first source/drains, and the second transistor includes a second channel layer, a second gate, and second source/drains. The first gate is disposed on the first channel layer, and the first channel layer is disposed between the first source/drains. The second gate is disposed on the second channel layer, and the second channel layer is disposed between the second source/drains. The device further includes a first source/drain contact, a second source/drain contact, and a source/drain via. The first source/drain contact is disposed on one of the first source/drains, and the second source/drain contact is disposed on one of the second source/drains. The source/drain via is disposed on the first source/drain contact and the second source/drain contact. The source/drain via is connected to the first source/drain contact and the second source/drain contact.

The source/drain via includes ruthenium and aluminum. In some embodiments, the source/drain via includes a ruthenium plug wrapped by an aluminum liner. In some embodiments, the source/drain via includes a ruthenium aluminide plug. In some embodiments, the source/drain via includes a ruthenium plug wrapped by a ruthenium aluminide liner. In some embodiments, the source/drain via spans a distance between a bottom of the one of the first source/drains and a top of the one of the second source/drains. In some embodiments, the second source/drain contact wraps a bottom end of the source/drain via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first contact opening in an insulation structure, wherein the first contact opening exposes a first source/drain of a source/drain stack;
forming a first source/drain contact in the first source/drain contact opening, wherein the first source/drain contact includes a first metallic material;
forming a via opening in the insulation structure, wherein the via opening exposes the first source/drain contact, the via opening extends into the insulation structure to at least a depth of a second source/drain of the source/drain stack in the insulation structure, the first source/drain is disposed over the second source/drain, and a portion of the insulation structure is disposed between the first source/drain and the second source/drain;
forming a source/drain via in the via opening and on the first source/drain contact, wherein the source/drain via includes a second metallic material and the second metallic material is different from the first metallic material;
forming a second contact opening in the insulation structure, wherein the second contact opening exposes the source/drain via and the second source/drain of the source/drain stack; and
forming a second source/drain contact in the second contact opening, wherein the second source/drain contact includes the first metallic material.

2. The method of claim 1, wherein the depth is a first depth and the first contact opening is formed to extend to at least a second depth of the portion of the insulation structure disposed between the first source/drain and the second source/drain.

3. The method of claim 1, wherein:
the forming the first source/drain contact includes forming a first tungsten plug;
the forming the second source/drain contact includes forming a second tungsten plug; and
the forming the source/drain via includes forming a ruthenium plug.

4. The method of claim 1, wherein:
the forming the first source/drain contact includes forming a first tungsten plug;
the forming the second source/drain contact includes forming a second tungsten plug; and
the forming the source/drain via includes forming a ruthenium aluminide plug.

5. The method of claim 1, further comprising forming the via opening to expose a top and a sidewall of the first source/drain contact.

6. The method of claim 1, further comprising patterning the source/drain via.

7. The method of claim 6, wherein the insulation structure is a first insulation structure and the patterning the source/drain via includes replacing a portion of the source/drain via with a second insulation structure.

8. The method of claim 6, wherein the patterning the source/drain via includes performing a reactive ion etch on the source/drain via.

9. The method of claim 1, wherein:
the insulation structure includes a first contact etch stop layer (CESL), a first interlayer dielectric (ILD) layer disposed over the first CESL, a second CESL disposed over the first ILD layer, a second ILD layer disposed over the second CESL, and a third ILD layer disposed over the second ILD layer, wherein the first CESL is disposed over the second source/drain, the second CESL is disposed over the first source/drain, and the portion of the insulation structure between the first source/drain and the second source/drain includes a portion of the first CESL and a portion of the first ILD layer; and
the method further includes:
forming the first contact opening to extend through the second ILD layer, the second CESL, and into the first ILD layer,
forming the via opening to extend through the third ILD layer, the second ILD layer, the second CESL, and into the first ILD layer, and
forming the second contact opening to extend through the first CESL and into the first ILD layer.

10. A method comprising:
forming a source/drain via opening adjacent to and spaced a lateral distance from a source/drain stack, wherein the source/drain stack includes an upper source/drain and a lower source/drain and the source/drain via opening extends vertically below the upper source/drain;
forming a ruthenium-and-aluminum source/drain via in the source/drain via opening;
forming an upper source/drain contact opening that exposes the upper source/drain and the ruthenium-and-aluminum source/drain via;
forming an upper source/drain contact in the upper source/drain contact opening;
forming a lower source/drain contact opening that exposes the lower source/drain and the ruthenium-and-aluminum source/drain via; and
forming a lower source/drain contact in the lower source/drain contact opening.

11. The method of claim 10, further comprising forming the source/drain via opening to extend from a distance above a top of the upper source/drain to a distance below a bottom of the upper source/drain, wherein the source/drain via opening further spans a distance between the upper source/drain and the lower source/drain.

12. The method of claim 11, further comprising forming the source/drain via opening to extend a distance below a top of the lower source/drain.

13. The method of claim 10, wherein the forming the ruthenium-and-aluminum source/drain via in the source/drain via opening includes:
depositing an aluminum liner that partially fills the source/drain via opening;
depositing a ruthenium layer over the aluminum liner that fills a remainder of the source/drain via opening, wherein the aluminum liner and the ruthenium layer are deposited by different types of deposition processes; and
performing a planarization process after depositing the ruthenium layer.

14. The method of claim 10, wherein the forming the ruthenium-and-aluminum source/drain via includes providing the ruthenium-and-aluminum source/drain via with an atomic concentration of ruthenium greater than about 45 atomic percent (at %).

15. The method of claim 10, further comprising patterning the ruthenium-and-aluminum source/drain via to reduce an overlap between the ruthenium-and-aluminum source/drain via and a gate of a stacked device structure that includes the source/drain stack.

16. The method of claim 10, further comprising forming the source/drain via opening in a gate cut isolation structure, such that the ruthenium-and-aluminum source/drain via is at least partially disposed in the gate cut isolation structure.

17. An interconnect structure comprising:
an insulation structure, wherein a portion of the insulation structure is disposed between a first source/drain and a second source/drain, wherein the first source/drain and the second source/drain belong to a source/drain stack of a stacked device structure;
a first source/drain contact disposed in the insulation structure, wherein the first source/drain contact extends from the first source/drain to at least a first depth of the portion of the insulation structure disposed between the first source/drain and the second source/drain;
a source/drain via disposed in the insulation structure, wherein the source/drain via extends from the first source/drain contact to at least a second depth of the second source/drain, wherein the second depth is greater than the first depth;
a second source/drain contact disposed in the insulation structure, wherein the second source/drain contact extends from the second source/drain to the source/drain via; and
wherein the first source/drain contact and the second source/drain contact include a first metallic material, the source/drain via includes a second metallic material different from the first metallic material, and the second metallic material includes ruthenium and aluminum.

18. The interconnect structure of claim 17, wherein:
the first source/drain contact includes a first tungsten plug;
the second source/drain contact includes a second tungsten plug; and
the source/drain via includes a ruthenium plug.

19. The interconnect structure of claim 18, wherein the source/drain via further includes an aluminum layer disposed between the ruthenium plug and the insulation structure.

20. The interconnect structure of claim 17, wherein:
the first source/drain contact includes a first tungsten plug;
the second source/drain contact includes a second tungsten plug; and
the source/drain via includes a ruthenium aluminide plug.
